(19) United States
(12) Patent Application Publication
(10) Pub. No.: US 2014/0175401 A1
(43) Pub. Date: Jun. 26, 2014

(54) RED PHOSPHORESCENT COMPOUND AND ORGANIC LIGHT EMITTING DIODE DEVICE USING THE SAME

(71) Applicant: LG DISPLAY CO., LTD., Seoul (KR)

(72) Inventor: Hyun-Cheol Jeong, Seoul (KR)

(73) Assignee: LG DISPLAY CO., LTD., Seoul (KR)

(21) Appl. No.: 14/086,216

(22) Filed: Nov. 21, 2013

(30) Foreign Application Priority Data
Dec. 26, 2012 (KR) 10-2012-0153126

(51) Int. Cl. H01L 51/00; H01L 51/50

(52) U.S. Cl. CPC H01L 51/0085; H01L 51/5028
USPC 257/40; 546/10

(57) ABSTRACT

A red phosphorescent compound has the following formula:

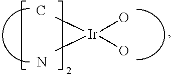

wherein

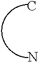

is

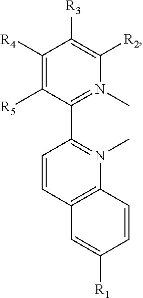

and R1 is selected from a group including C1˜C6 alkyl, C1˜C6 alkoxy, trimethylsilyl, trifluoromethyl, halogen and cyanide, and wherein each of R2, R3, R4 and R5 is independently selected from a group including hydrogen, C1˜C6 alkyl, C1˜C6 alkoxy, halogen, trimethylsilyl and trifluoromethyl.

The present application claims the benefit of priority to Korean Patent Application No. 10-2012-0153126 filed in Korea on Dec. 26, 2012, which is herein incorporated by reference in its entirety.

### BACKGROUND

1. Field of the Disclosure

The present disclosure relates to a red phosphorescent compound and an organic light emitting diode (OLED) device and more particularly to a red phosphorescent compound having excellent color purity and high internal quantum efficiency and an OLED device using the same.

2. Discussion of the Related Art

Recently, requirements for flat panel display devices, such as a liquid crystal display device and a plasma display panel, have increased. However, these flat panel display devices have relatively slow response time and narrow viewing angle in comparison to the cathode ray tube (CRT).

An organic light emitting diode (OLED) device is one of next-generation flat panel display devices being capable of resolving the above problems and occupying small area.

Elements of the OLED device can be formed on a flexible substrate such as a plastic substrate. In addition, the OLED device has advantages in the viewing angle, the driving voltage, the power consumption and the color purity. Moreover, the OLED device is adequate to produce full-color images.

Generally, the emitting diode of the OLED device includes the anode, the hole injecting layer (HIL), the hole transporting layer (HTL), the emitting material layer (EML), the electron transporting layer (ETL), the electron injecting layer (EIL) and the cathode.

The OLED device emits light by injecting electrons from a cathode as an electron injection electrode and holes from an anode as a hole injection electrode into an emission compound layer, combining the electrons with the holes, generating an exciton, and transiting the exciton from an excited state to a ground state.

The emitting principle may be classified into fluorescent emission and phosphorescent emission. In the fluorescent emission, the organic molecule in the singlet exited state is transited to the ground state such that light is emitted. On the other hand, in the phosphorescent emission, the organic molecule in the triplet exited state is transited to the ground state such that light is emitted.

When the emitting material layer emits light corresponding to an energy band gap, the singlet exciton having 0 spin and the triplet exciton having 1 spin are generated with a ratio of 1:3. The ground state of the organic material is the singlet state such that the singlet exciton can be transited to the ground state with emitting light. However, since the triplet exciton can not be transited with emitting light, the internal quantum efficiency of the OLED device using the fluorescent material is limited within 25%.

On the other hand, if the spin-orbital coupling momentum is high, the singlet state and the triplet state are mixed such that an inter-system crossing is generated between the singlet state and the triplet state and the triplet exciton also can be transited to the ground state with emitting light. The phosphorescent material can use the triplet exciton as well as the singlet exciton such that the OLED device using the phosphorescent material may have 100% internal quantum efficiency.

Recently, iridium complex, e.g., bis(2-phenyl quino line)(acetylacetonate)iridium(III)(Ir(2-phq)2(acac)), bis(2-benzo[b]thiophene-2-yl-pyridine)(acetylacetonate)iridium(III)(Ir(btp)2(acac)) and tris(2-phenylquinoline)iridium(III)(Ir(2-phq)3), as a dopant is introduced.

To obtain high current emitting efficiency (Cd/A) with the phosphorescent material, excellent internal quantum efficiency, high color purity and long life-time are required. Particularly, referring to FIG. 1, as the color purity becomes higher, i.e., higher CIE(X), the color sensitivity becomes bad. As a result, with the high internal quantum efficiency, it is very difficult to obtain emitting efficiency.

Accordingly, new red phosphorescent compound having excellent color purity (CIE(X)≧0.65) and high emitting efficiency is required.

### SUMMARY

A red phosphorescent compound having the following formula:

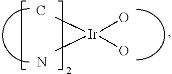

wherein

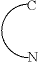

is

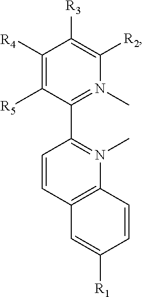

and R1 is selected from a group including C1˜C6 alkyl, C1˜C6 alkoxy, trimethylsilyl, trifluoromethyl, halogen and cyanide, and wherein each of R2, R3, R4 and R5 is independently selected from a group including hydrogen, C1˜C6 alkyl, C1˜C6 alkoxy, halogen, trimethylsilyl and trifluoromethyl.

In another aspect of the present invention, the present invention provides an organic light emitting diode device, comprising: a first electrode; a second electrode facing the first electrode; and an emitting material layer between the first and second electrodes and including a red phosphorescent compound having the following formula:

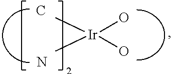

wherein

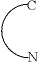

is

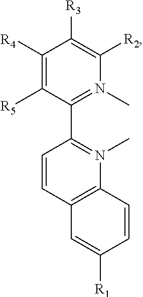

and R1 is selected from a group including C1˜C6 alkyl, C1˜C6 alkoxy, trimethylsilyl, trifluoromethyl, halogen and cyanide, and wherein each of R2, R3, R4 and R5 is independently selected from a group including hydrogen, C1˜C6 alkyl, C1˜C6 alkoxy, halogen, trimethylsilyl and trifluoromethyl.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention and together with the description serve to explain the principles of the invention.

FIG. 1 is a graph showing a relation of a color purity and a visible sensitivity; and

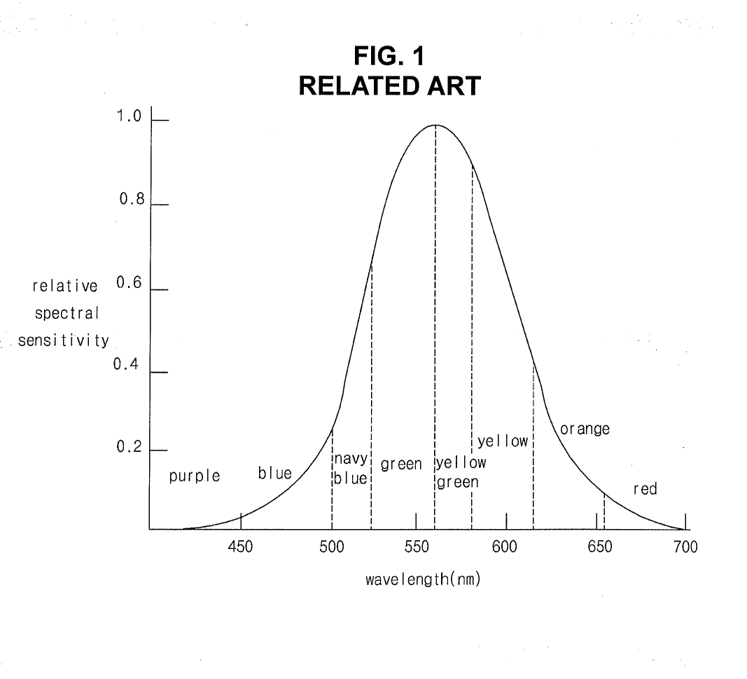

FIG. 2 is a schematic cross-sectional view of an OELD device according to the present invention.

### DETAILED DESCRIPTION OF THE EXEMPLARY EMBODIMENTS

Reference will now be made in detail to the preferred embodiments, examples of which are illustrated in the accompanying drawings.

The present invention provides a red phosphorescent compound having improved emitting efficiency with excellent color purity and high internal quantum efficiency and an OLED device using the red phosphorescent compound.

As mentioned above, the related art red phosphorescent compound having good color purity has bad visible sensitivity. As a result, it is very difficult to improve the emitting efficiency.

In the present invention, the red phosphorescent compound has improved emitting properties and efficiency. Particularly, the color purity of the red phosphorescent compound is remarkably improved. The red phosphorescent compound may be used as a dopant of an emitting material layer of the emitting diode for the OLED device.

The red phosphorescent compound of the present invention includes pyridine and quinoline as a main ligand and is represented by following Formula 1.

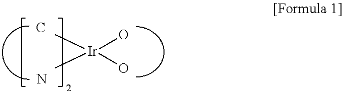

In the above Formula 1,

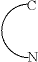

is

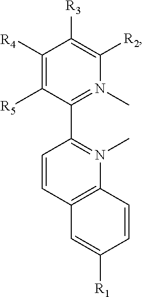

and R1 is selected from a group including C1˜C6 alkyl, C1˜C6 alkoxy, trimethylsilyl, trifluoromethyl, halogen and cyanide. Each of R2, R3, R4 and R5 is independently selected from a group including hydrogen, C1˜C6 alkyl, C1˜C6 alkoxy, halogen, trimethylsilyl and trifluoromethyl.

In this instance, at least one of R2 to R5, which are substituents of pyridine part, may not be hydrogen. For example, at least one of R2 to R5 may be one of C1˜C6 alkyl and C1˜C6 alkoxy.

C1˜C6 alkyl for R1 of quinoline part and R2 to R5 of pyridine part may be substituted by fluorine atom. For example, R1 to R5 may be independently selected from methyl, ethyl, n-propyl, i-propyl, n-butyl, and t-butyl. C1˜C6 alkyl substituent for R1 to R5 may be substituted by one to three fluorine atoms. Beneficially, R1 to R5 may be C1 to C6 alkyl substituted by three fluorine atoms. More beneficially, R1 to R5 may be trifluoromethyl. However, it is not limited thereto.

C1˜C6 alkoxy for R1 of quinoline part and R2 to R5 of pyridine part may be independently selected from methoxy, ethoxy, n-propoxy, i-propoxy, n-butoxy, i-butoxy and t-butoxy.

In addition, halogen for R1 of quinoline part and R2 to R5 of pyridine part is one of fluorine (F), chorine (Cl), bromine (Br) and iodine (I).

For example, the main ligand

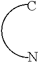

of the Formula 1 may be one of followings in Formula 2.

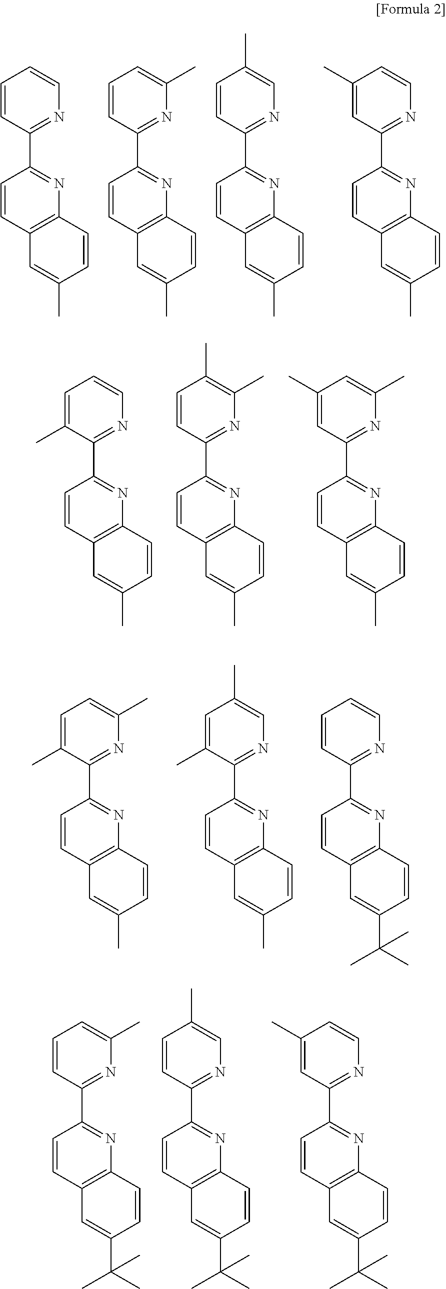

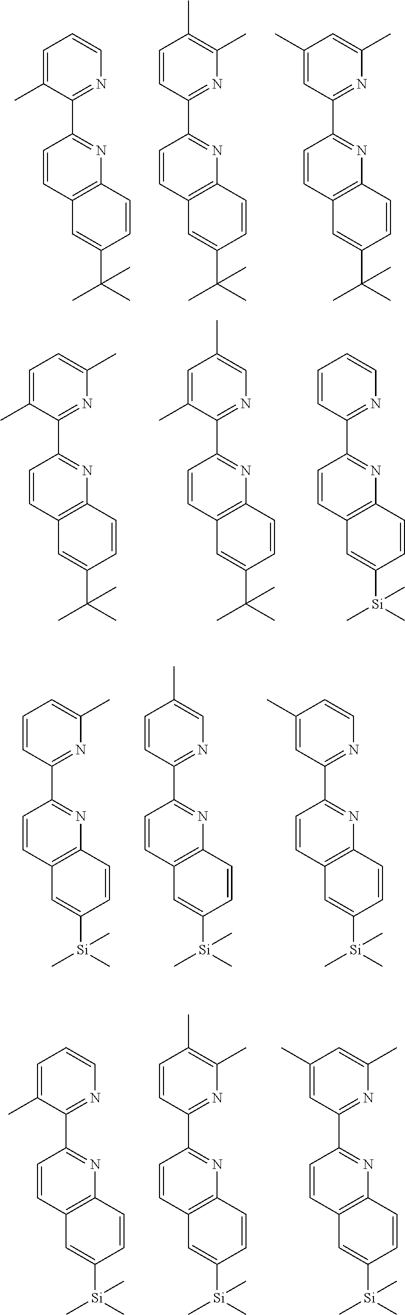

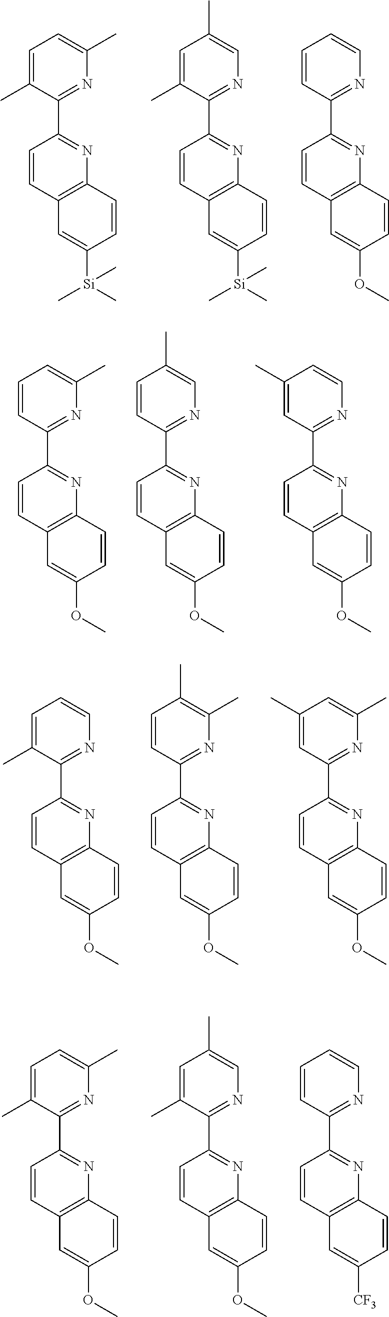

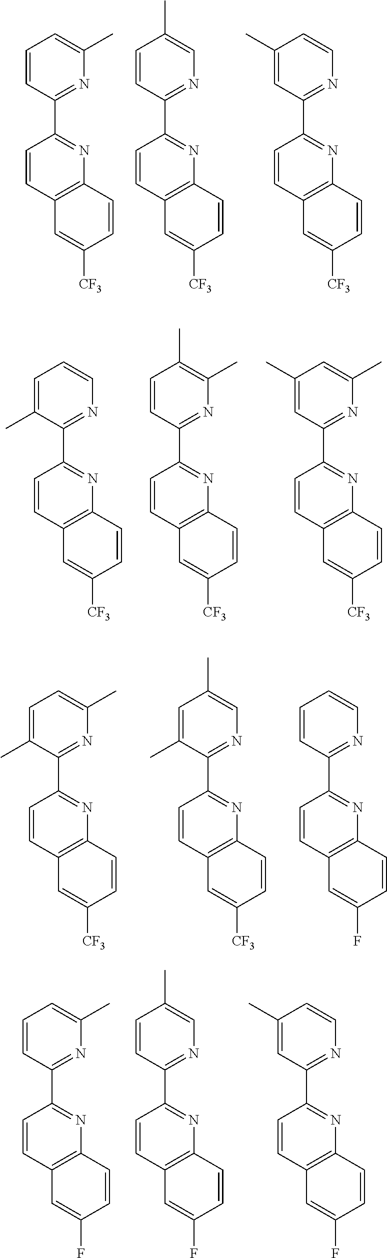

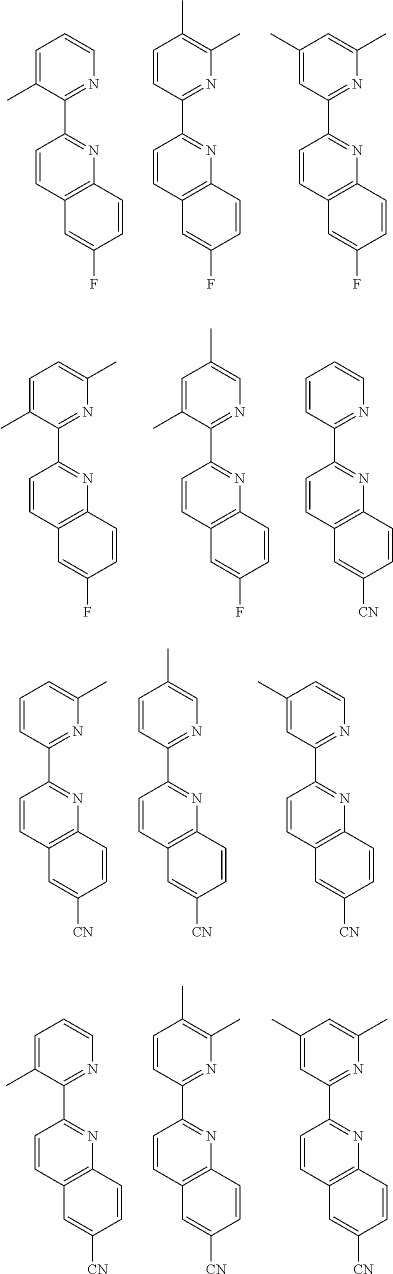

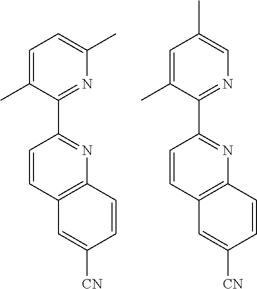

The ancilliary ligand

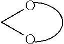

of the Formula 1 may be selected from 2,4-ppentanedione

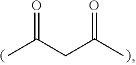

2,2,6,6-tetramethylheptane-3,5-dione

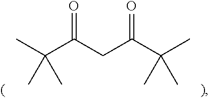

1,3-propanedione

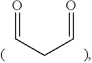

1,3-butanedione

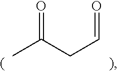

3,5-heptanedione

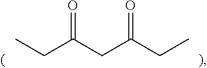

1,1,1-trifluoro-2,4-pentanedione

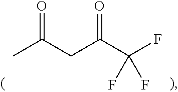

1,1,1,5,5,5-hexafluoro-2,4-pentanedione

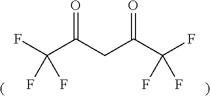 [SMILES: O=C(CC(=O)C(F)(F)F)C(F)(F)F]

and 2,2-dimethyl-3,5-hexanedione

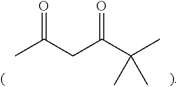

The red phosphorescent compound as iridium complex, which includes the above main ligand and the above ancilliary ligand in co-ordination bond, may be selected from following materials in Formula 3. For the sake of explanation, the materials are marked by A-01 to A-105.

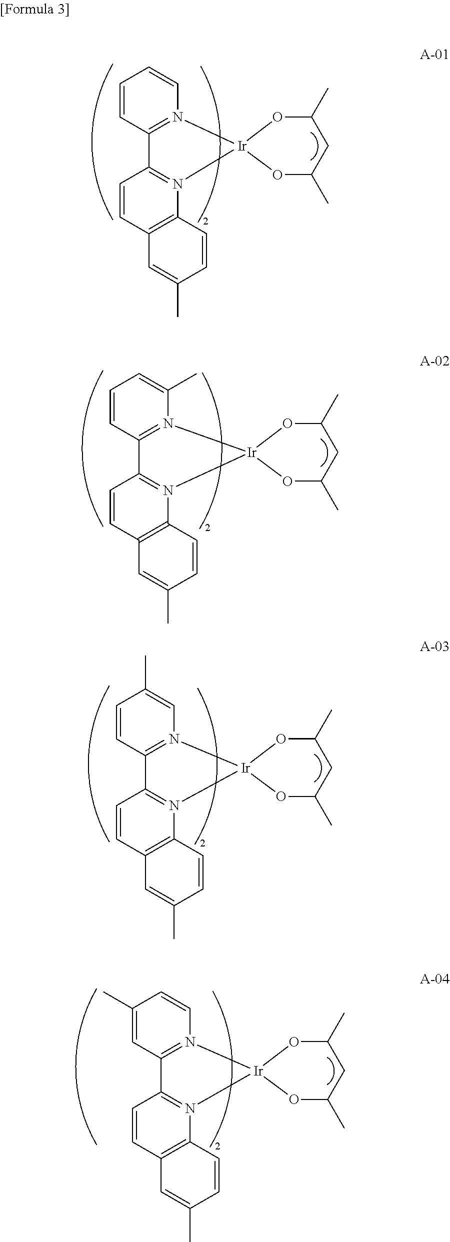

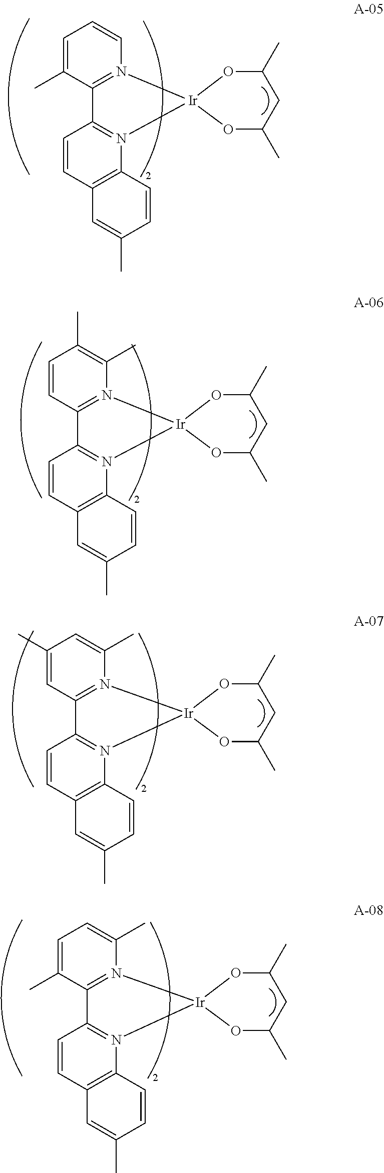

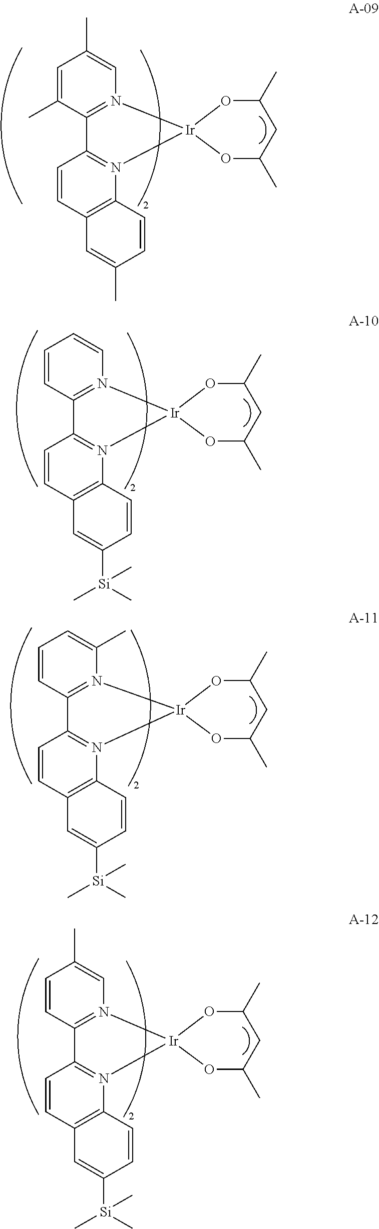

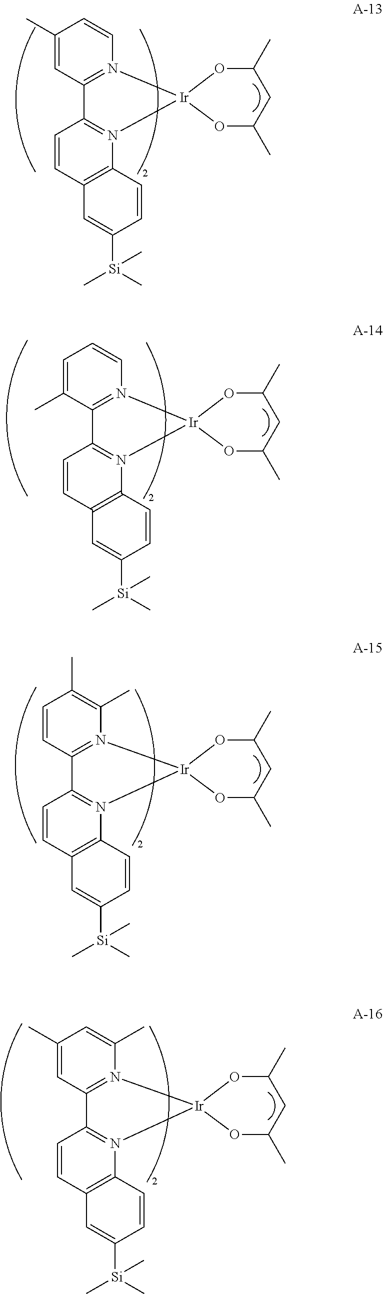

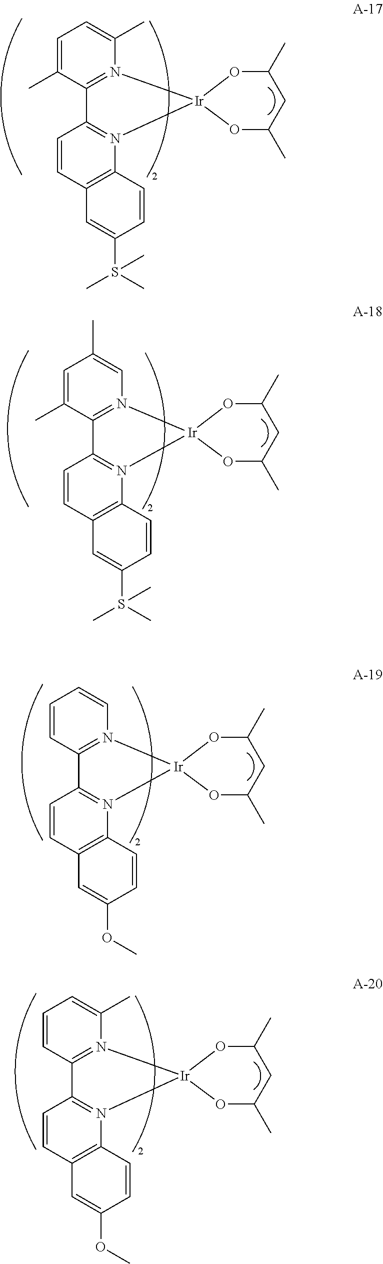

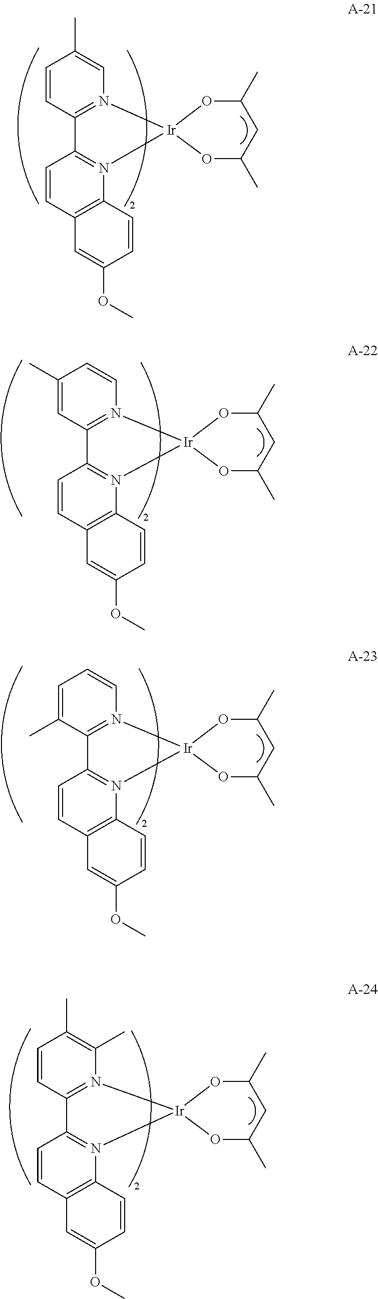

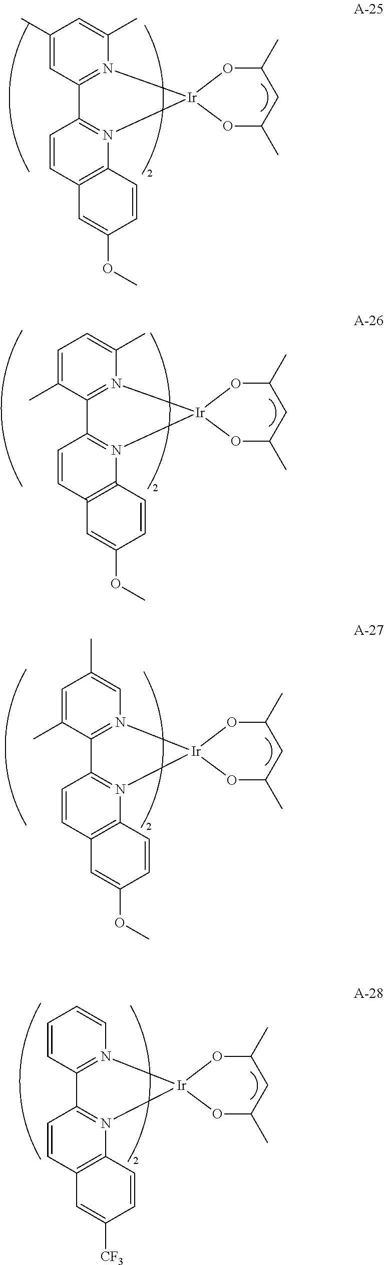

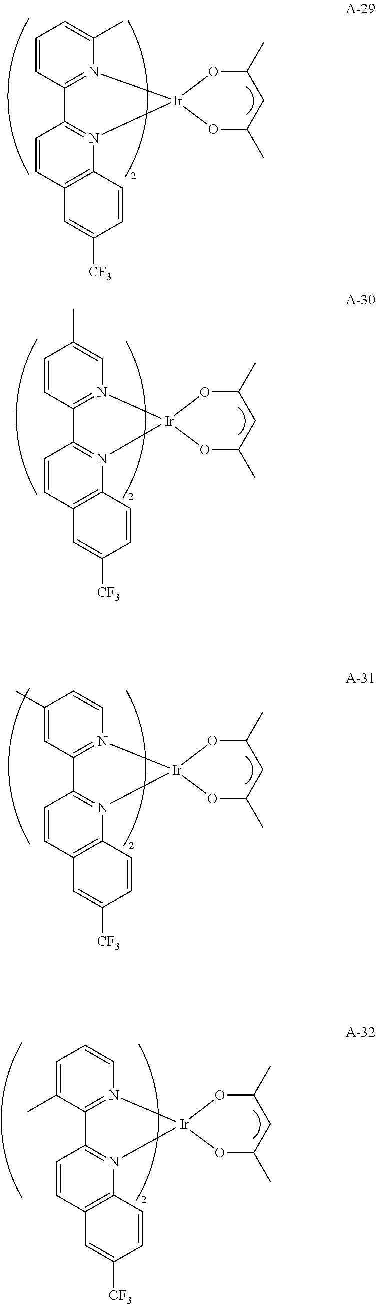

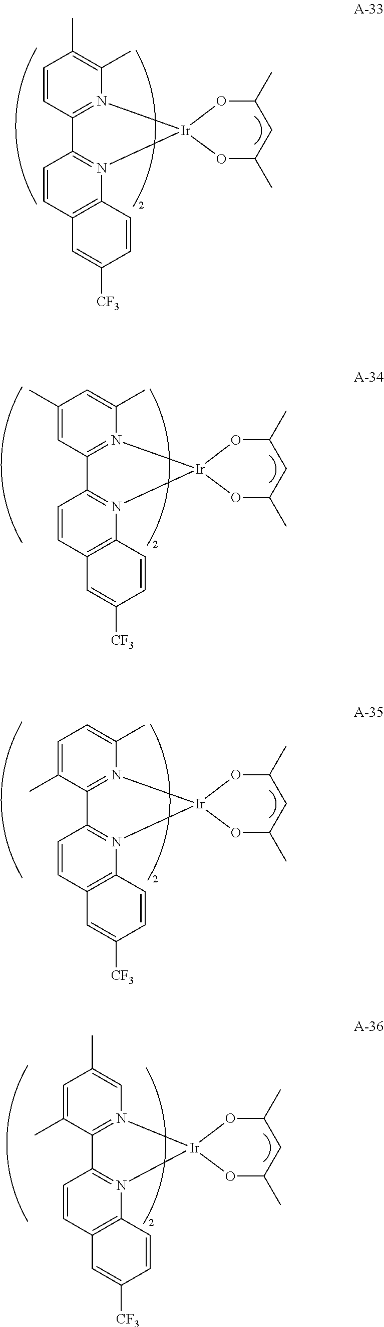

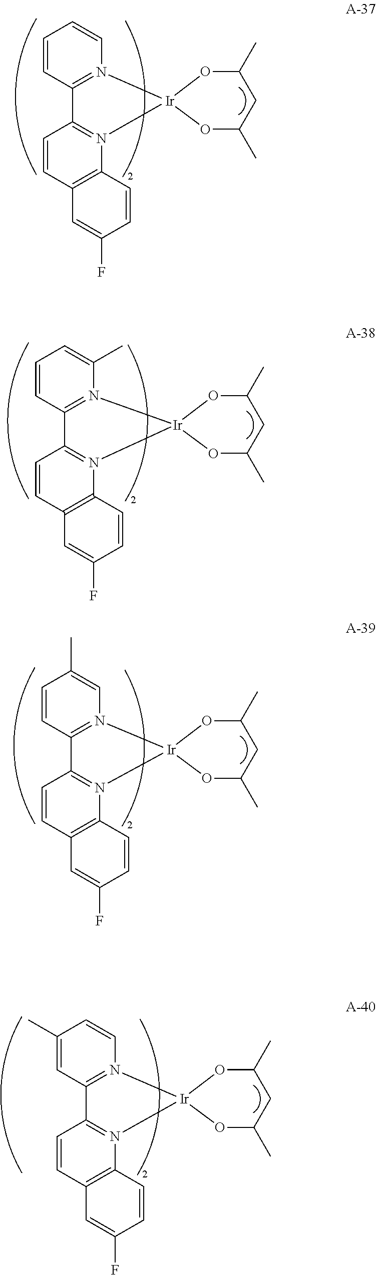

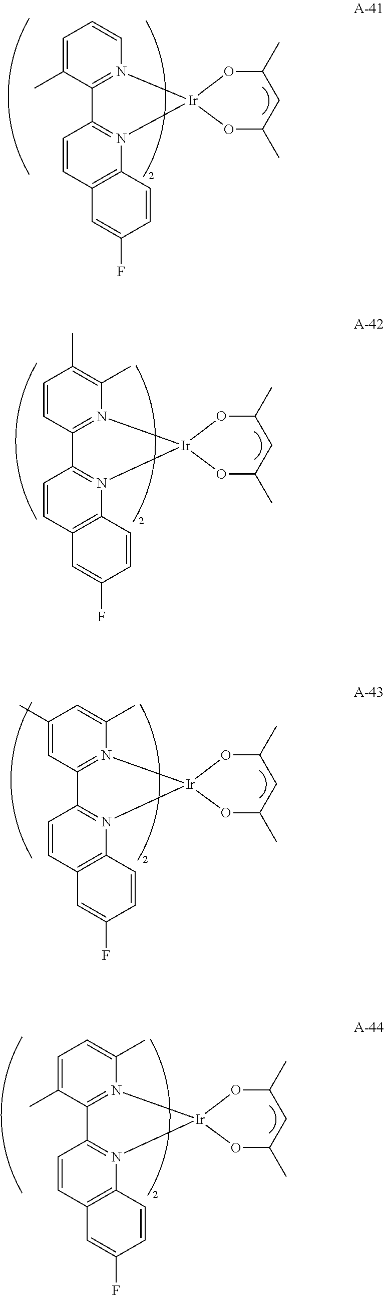

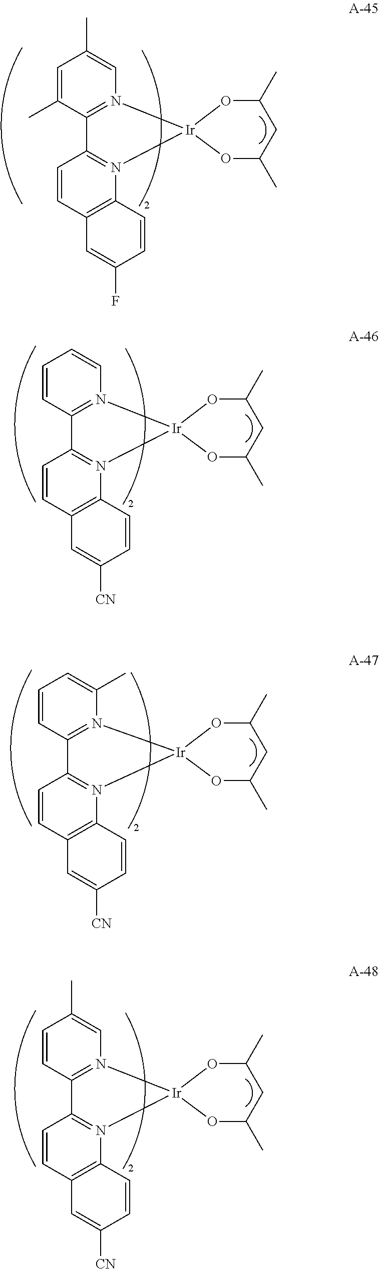

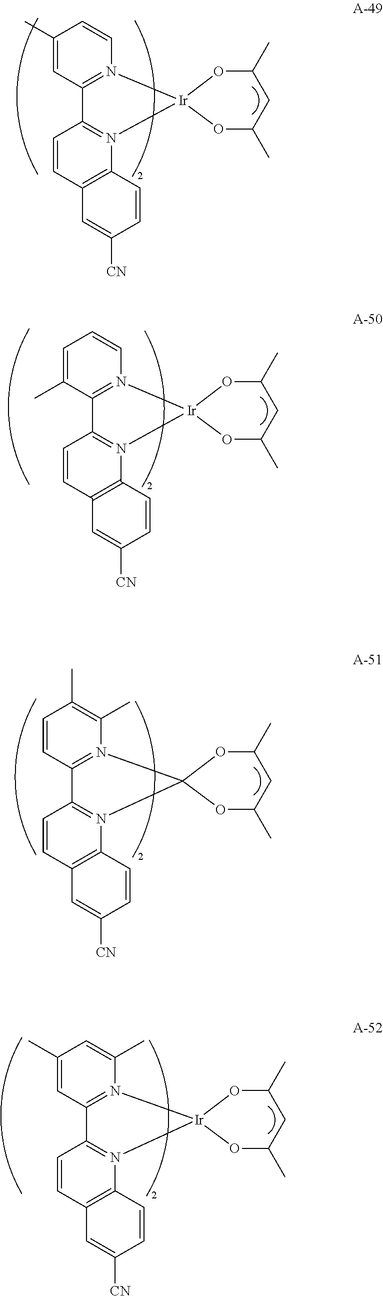

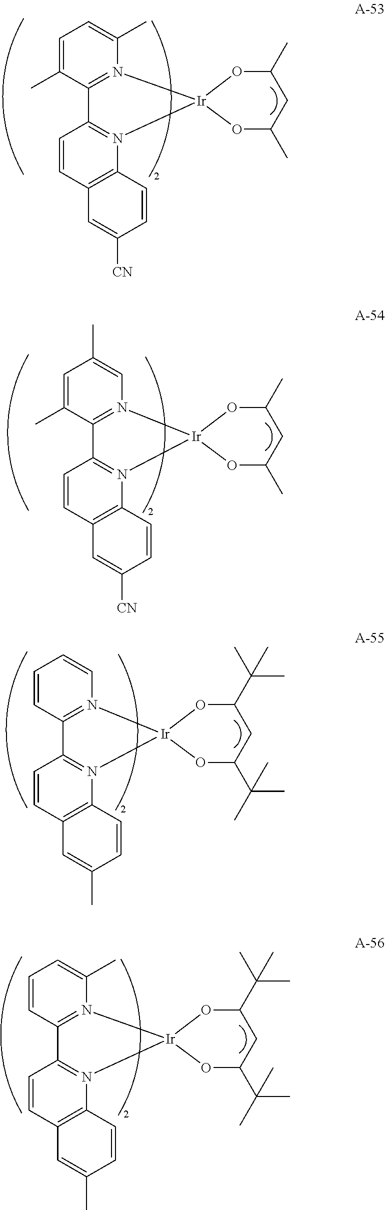

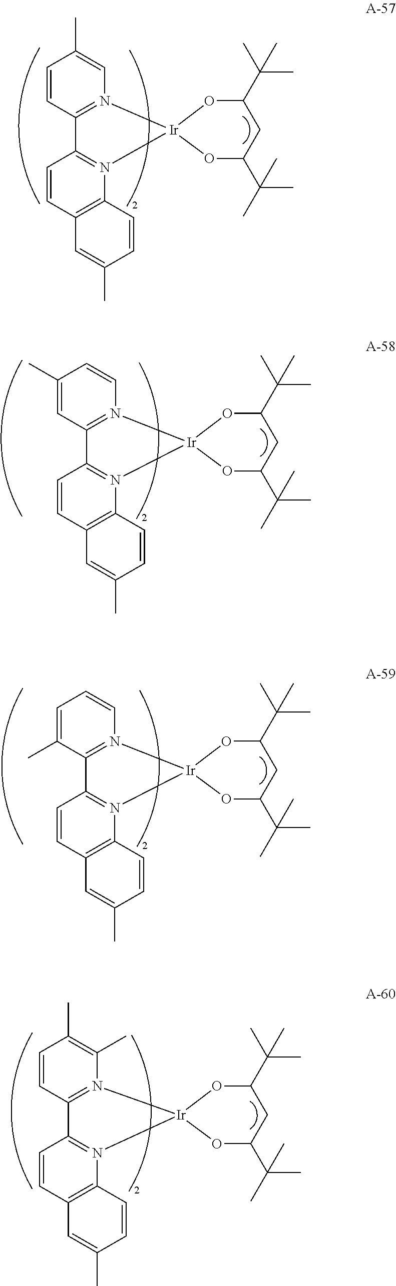

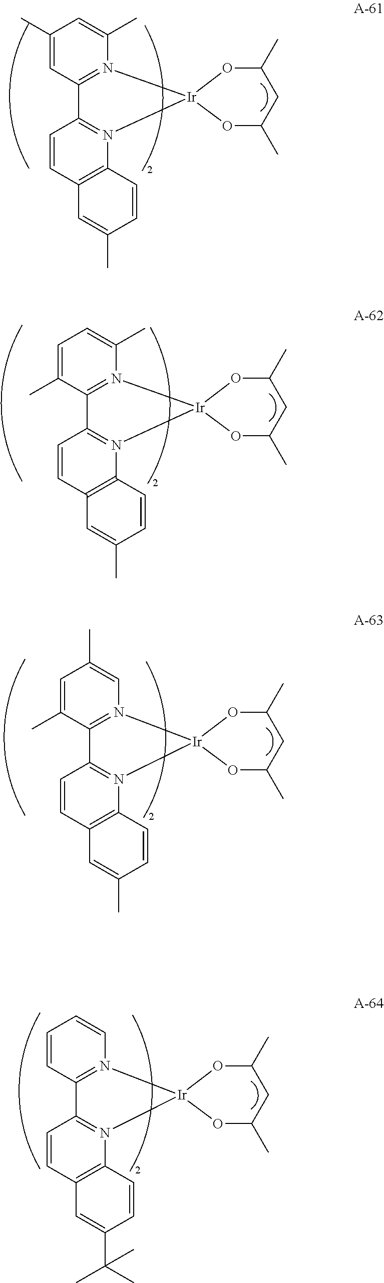

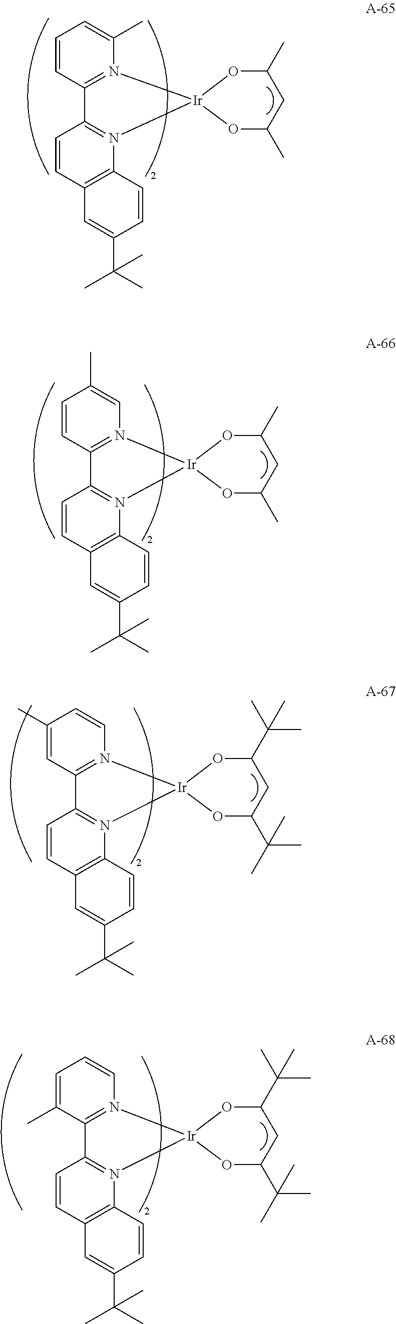

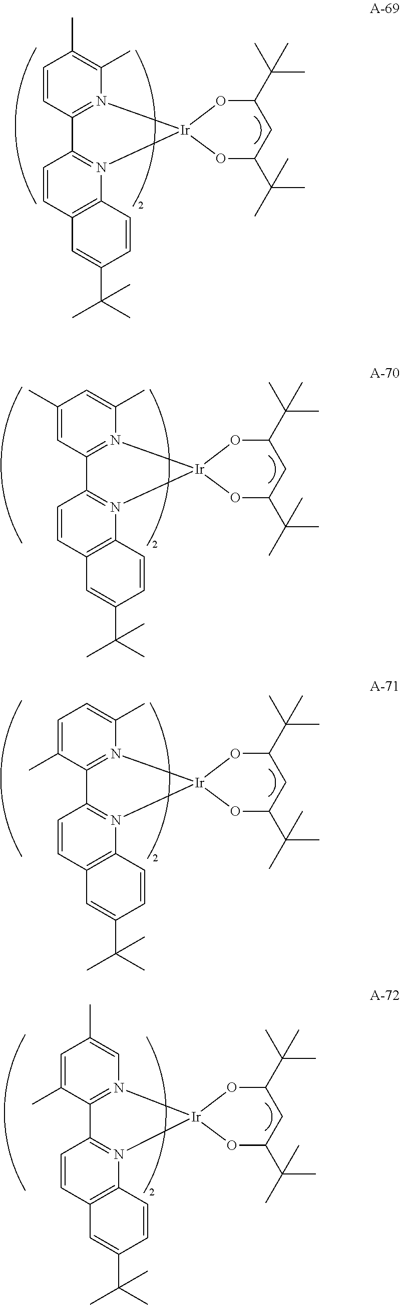

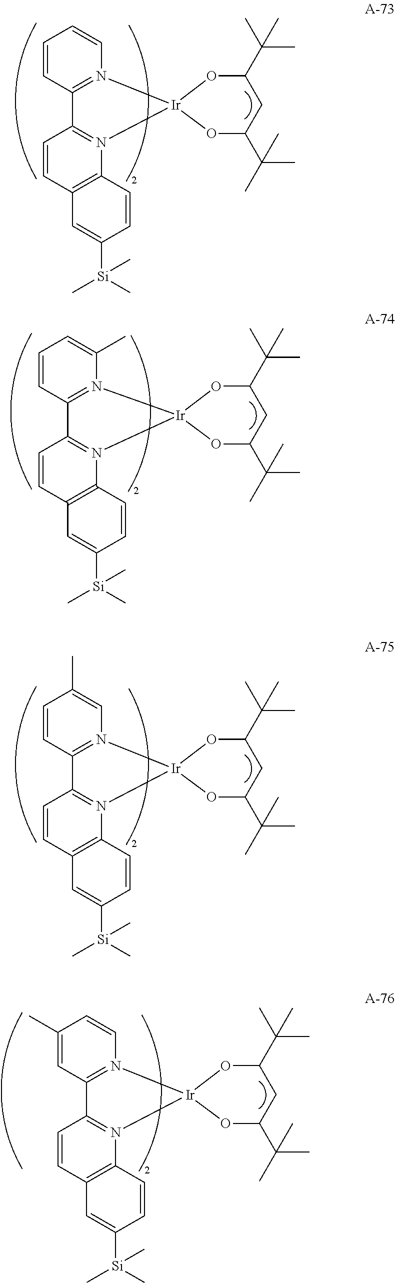

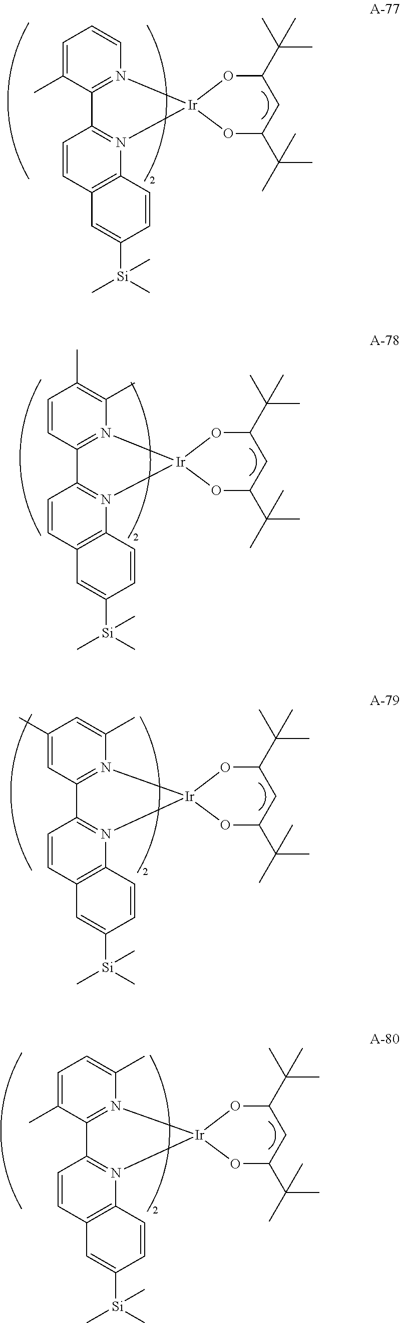

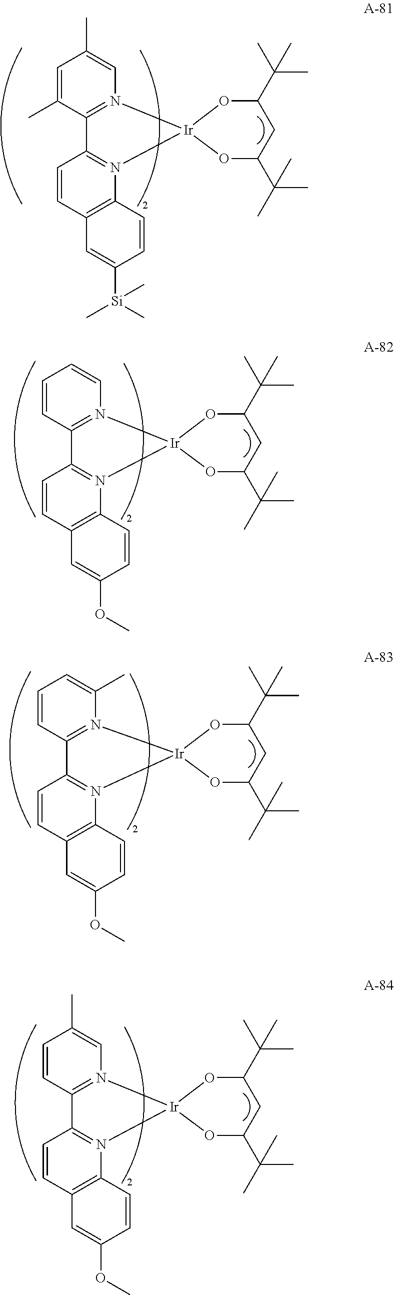

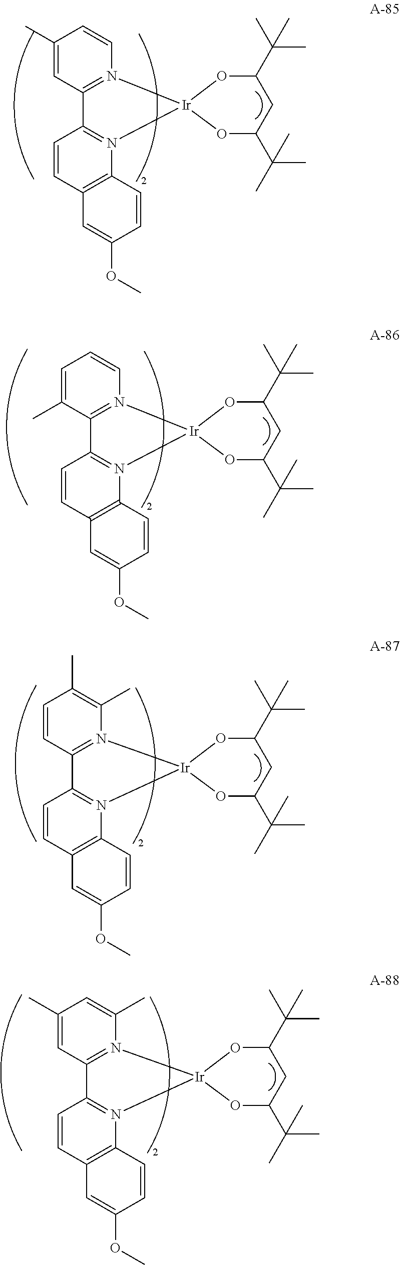

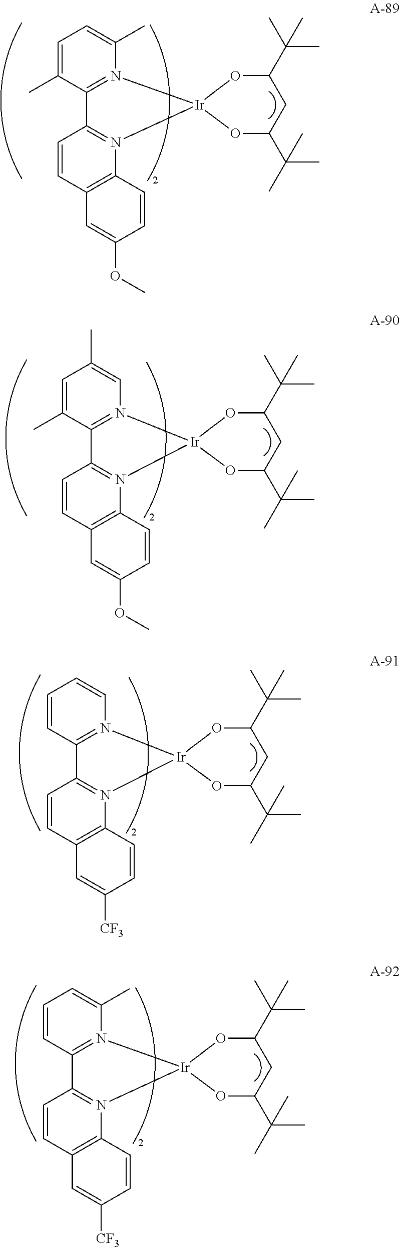

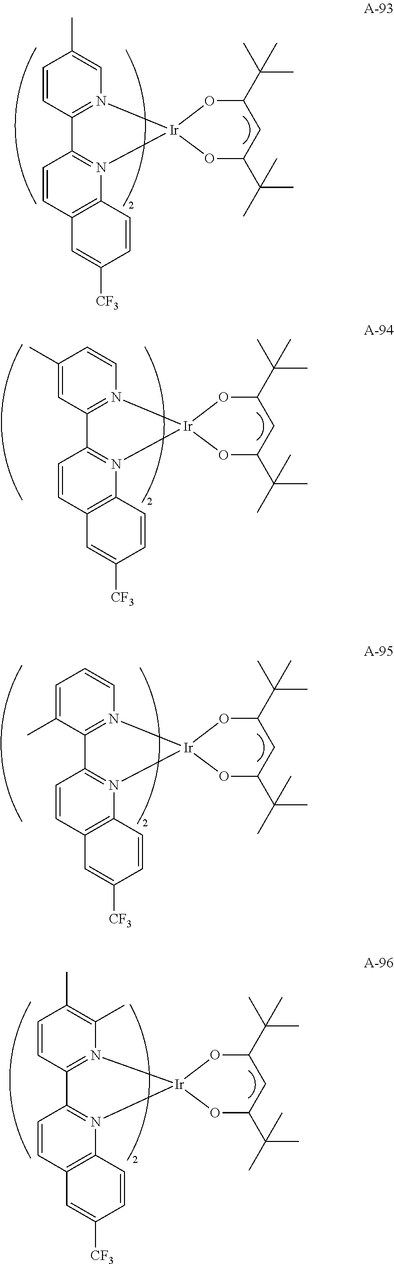

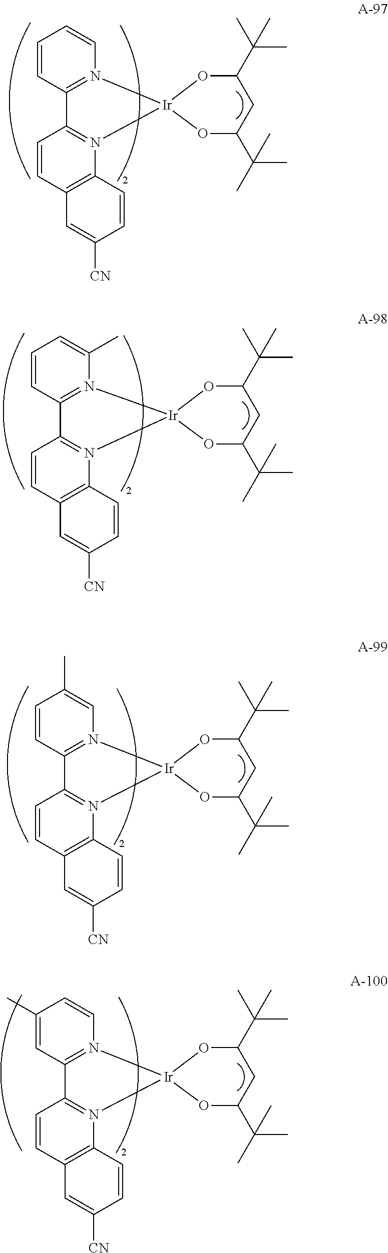

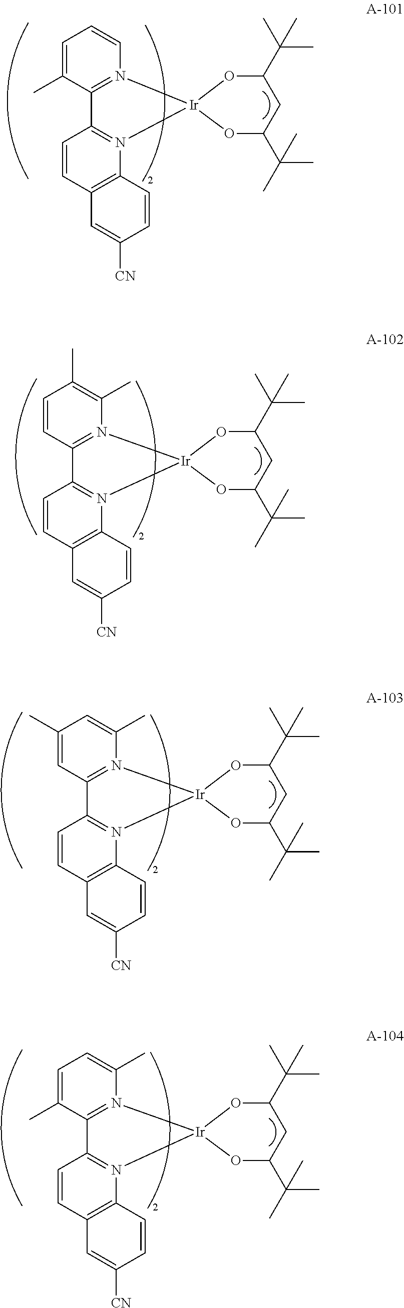

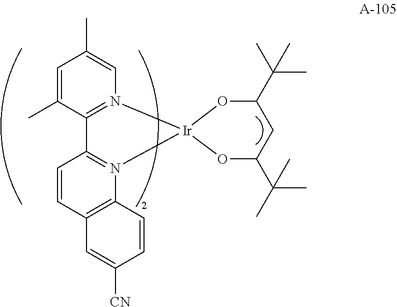

As described above, the iridium complex of the present invention includes pyridyl-quinoline ligand, as the main ligand, including nitrogen atom. Namely, the iridium complex includes nitrogen atoms having excellent electron affinity. Accordingly, the electron mobility in the emitting diode using the iridium complex of the present invention is improved.

In addition, with the substituents, such as alkyl, alkoxy, and alkylsilyl, for the main ligand, the emission efficiency, the lift-time and the color purity of the OLED device are improved. For example, the red phosphorescent compound of the Formula 1 may be used as a dopant for an emitting material layer of the OLED device.

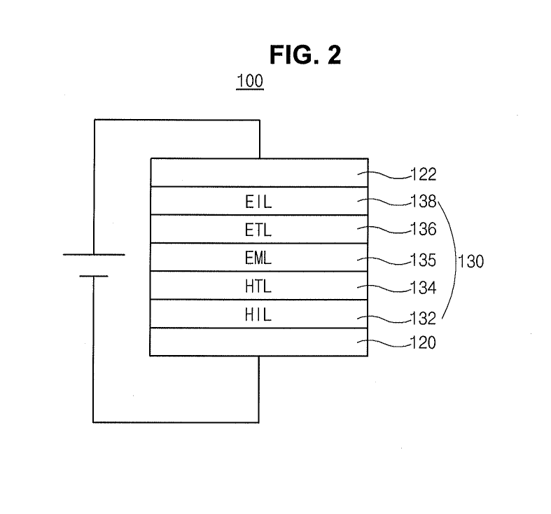

Referring to FIG. 2, which is a schematic cross-sectional view of an OLED device according to the present invention, the OLED device 100 includes a transparent substrate (not shown), a first electrode 120 over the transparent substrate, a second electrode 122 over the first electrode 120 and an organic material layer 130 between the first and second electrodes 120 and 122.

The first and second electrodes 120 and 122 respectively serve as anode and cathode. The first electrode 120 as the anode is formed of a material having a higher work function than a material of the second electrode 122 as the cathode. The first electrode 120 has properties of efficiently injecting holes as a positive-charged carrier. In addition, the first electrode 120 may be transparent and have good conductivity. The first electrode 120 is formed of metals, mixed metals, metal alloys, mixed metal oxides or conductive polymers. For example, the first electrode 120 may be formed of one of vanadium, copper, gold, their alloys, indium-tin-oxide (ITO), indium-zinc-oxide (IZO), fluorine-doped tin oxide, ZnO—Ga₂O₃, ZnO—Al₂O₃, SnO₂—Sb₂O₃, carbon black, and graphene. Beneficially, the first electrode 120 may be formed of ITO.

On the other hand, the second electrode 122 over the electron injecting layer 138 has properties of efficiently injecting electrons as a negative-charged carrier. For example, the second electrode 122 may be formed of one of gold, aluminum (Al), copper, silver, their alloys, Al-calcium alloy, magnesium-silver alloy, Al-lithium alloy, Al-lithiumoxide alloy, rear-earth metals, lanthanide metals, actinide metals. Beneficially, the second electrode 122 may be formed of Al or Al-calcium alloy. A passivation layer may be formed on the second electrode 120.

Each of the first and second electrodes 120 and 122 may be formed of a vapor deposition process and have a thickness of about 5 to 400 nm.

To increase emission efficiency, the organic material layer 130 may have a multi-layered structure. For example, the organic material layer 130 may include a hole injecting layer (HIL) 132, a hole transporting layer (HTL) 134, the emitting material layer (EML) 135, the electron transporting layer (ETL) 136 and the electron injecting layer (EIL) 138. In this instance, the compound of the present invention is used for the EML 135 as a dopant.

An interfacial property between the first electrode 120 of ITO and the HTL 134 of an organic material is improved by the HIL 132 between the first electrode 120 and the HTL 134. In addition, a surface of the uneven ITO layer is planarized by the HIL 132. For example, the HIL 132 may be formed of one of copper phthlalocyanine (CuPc), aromatic amines, such as 4,4′,4″-tris[methylphenyl(phenyl)amino]triphenylamine (m-MTDATA), 4,4′,4″-tris[1-naphthyl(phenyl)amino]triphenylamine (1-TNATA), 4,4′,4″-tris[2-naphthyl(phenyl)amino]triphenylamine(2-TNATA), and 1,3,5-tris [N-(4-diphenylaminophenyl)phenylamino]benzene(p-DPA-TDAB), 4,4′-bis[N-[4-{N,N-bis(3-methylphenyl)amino}phenyl]-N-phenylamino]biphenyl (DNTPD), and hexaazatriphenylene-hexacarbonitirile (HAT-CN). The HIL 132 may have a thickness of about 10 to 100 nm.

To securely provide the holes from the first electrode 120 through the HIL 132 to the EML 135, the HTL 134 is formed of a material having highest occupied molecular orbital (HOMO) value higher than the EML 135. For example, the HTL 134 may be formed of one of N,N-bis(3-methylphenyl)-N,N′-diphenyl-[1,1′-diphenyl-4,4′-diamine(TPD), N,N′-bis(1-naphthyl)-N,N′-biphenyl-[1,1′-biphenyl]-4,4′-diamine(TPB), N,N′-bis-(1-naphyl)-N,N′-diphenyl-1,1-biphenyl-4,4′-diamine(NPB), 1-naphthyl-N-phenyl-aminobiphenyl(NPD), triphenylamine(TPA), bis[4-(N,N-diethylamino)-2-methylphenyl](4-methylphenyl)methane(MPMP)-N,N′,N′-tetrakis(4-methylphenyl)-(1,1′-biphenyl)-4,4-diamine(TTB), and N,N′-bis(4-methylphenyl)-N,N′-bis(4-ethylphenyl)-[1,1′(3,3′-dimethyl)biphenyl]-4,4′-diamine(ETPD). The HTL 134 may be formed of NPB or NPD and have a thickness of about 30 to 60 nm.

The EML 135 on the HTL includes the red phosphorescent compound of the present invention. For example, the red phosphorescent compound of the present invention may be used as a dopant in the EML 135. The red phosphorescent compound may be doped with a weight % of about 0.1 to 50 of the EML 135.

The EML 135 may further include a host to improve the emitting efficiency and preventing the color shift and the quenching problem. For example, Al-metal complex, zinc(Zn)-metal complex or carbazole derivative may be used for the host. Al-complex may be aluminum(III)bis {2-methyl-8-quinolinato}-4-phnylephenolate(BAlq). Al-metal complex and Zn-metal complex include at least one of phenylyl, biphenylyl, quinolyl, iso-quinolyl, methyl-quinolyl, dimethylquinolyl and dimethyl-iso-quinolyl. Carbazole derivative includes one of 4,4′-N,N′-dicarbazole-1,1-biphenyl(CBP) and (N,N-dicarbazoyl-3,5-benzene(mCP). The EML 135 may have a thickness of about 5 to 200 nm, beneficially 30 to 60 nm.

The EIL 138 and ETL 136 are formed between the EML 135 and the second electrode 122. The EIL 138 may be formed of one of LiF, BaF₂ and CsF. The ETL 136 is formed of a material having a relatively high electron mobility. For example, the ETL 136 may be formed of one of tris(8-hydroxyquinolinato)aluminum(Alq3), 9-dimethyl-4,7-diphenyl-1,10-phenanthroline(DDPA), 2-(4-biphenyl)-5-(4-tert-butyl)-1,3,4-oxadizole(PBD), 3-(4-biphenyl)-4-phenyl-5-(4-tert-butyl)-1,2,4-triazole(TAZ) and phenylquinozaline. The ETL 136 may have a thickness of about 5 to 150 nm.

Although not shown, a hole blocking layer (HBL) of a material having a relatively low HOMO level may be formed between the EML 135 and the ETL 136. For example, the HBL may be formed of one of 2,9-dimethyl-4,7-diphenyl-1,10-phenanthroline(BCP) and have a thickness of about 5 to 150 nm.

Hereinafter, synthesis of the red phosphorescent compound of the present invention is explained. However, the synthesis of the red phosphorescent compound of the present invention is not limited thereto.

### 1. Synthesis of A-02 Compound

1) 2-(6′-methypyridyl)-6-methylquinoline

2-(6′-methypyridyl)-6-methylquinoline was synthesized by following Reaction Formula 1-1.

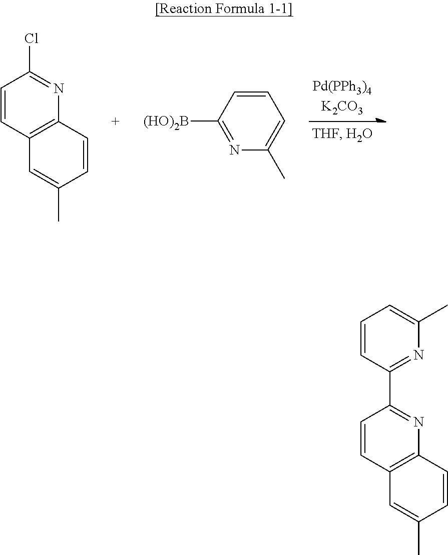

2-chloro-6-methylquinoline (5 g, 0.02 mol), 6-methyl-2-pyridine boronic acid (4.0 g, 0.03 mol), K₂CO₃ (8.3 g) and a little Pd(PPh₃)₄ were put in THF/H₂O (60 mL/60 mL) in a two-neck flask and refluxed for about 18 hours. After confirming completion of the reaction by TLC, the solution was cooled into a room temperature. The solution was extracted with methylenechloride, and the solvent are evaporated. The resultant was silicagel-columned and purified to obtain 2-(6′-methypyridyl)-6-methylquinoline (4.9 g, yield: 80%).

### 2) Chloro-Bridge Dimer Complex

Chloro-bridge dimer complex was synthesized by following Reaction Formula 1-2.

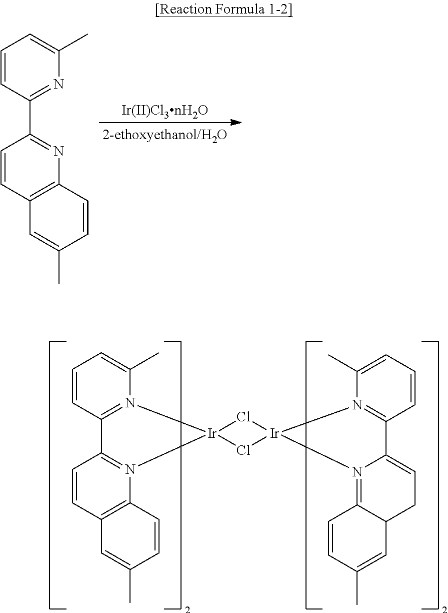

Iridium chloride (5 mmol) and 2-(6′-methypyridyl)-6-methylquinoline (10 mmol) was put in a solution (30 mL) of 2-ehoxyethanol and distilled H₂O (3:1) and refluxed for about 24 hours. After filtering the solids formed by adding water to the resulting solution, the solids were washed in several times with distilled water to obtain chloro-bridged dimer complex.

3) Iridium(III) (2-(6′-methylpyridyl)-6-methylquinoline-N,C2′)(2,4-pentanedionate-O,O)[A-02]

A-02 compound was synthesized by following Reaction Formula 1-3.

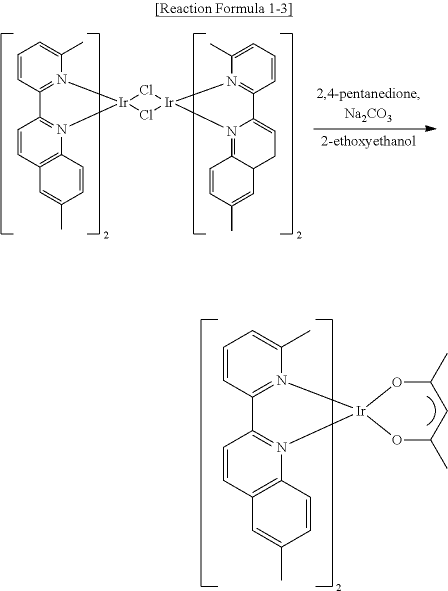

The above chloro-bridged dimer complex (1 mmol), 2,4-pentanedione (3 mmol) and Na₂CO₃(6 mmol) were put into 2-ethoxyethanol (30 mL) and refluxed for about 24 hours. The resulting solution was cooled, and distilled water was added. The resulting solution was filtered to obtain solids. The solids were dissolved in dichloromethane and filtered using silica gel. The solids were re-crystallized with dichloromethane and methanol to obtain A-02 compound.

### 2. Synthesis of A-11 Compound

1) 2-(6′-methylpyridyl)-6-trimethlysillylquinoline

2-(6′-methylpyridyl)-6-trimethlysillylquinoline was synthesized by following Reaction Formula 2-1.

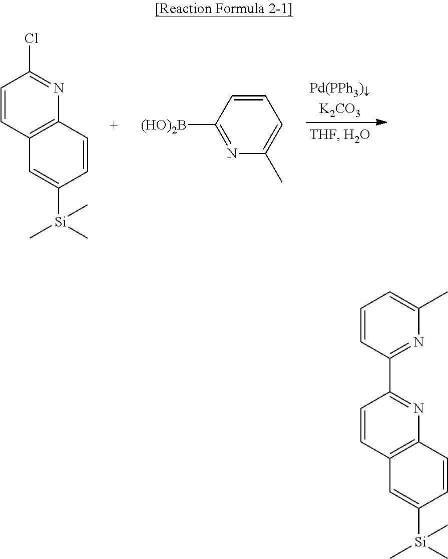

2-chloro-6-trimethylsilylquinoline (5 g, 0.02 mol), 6-methyl-2-pyridine boronic acid (4.1 g, 0.03 mol), K₂CO₃ (8.3 g) and a little Pd(PPh₃)₄ were put in THF/H₂O (60 mL/60 mL) in a two-neck flask and refluxed for about 18 hours. After confirming completion of the reaction by TLC, the solution was cooled into a room temperature. The solution was extracted with methylenechloride, and the solvent are evaporated. The resultant was silicagel-columned and purified to obtain 2-(6′-methylpyridyl)-6-trimethlysillylquinoline (5.0 g, yield: 80%).

### 2) Chloro-Bridge Dimer Complex

Chloro-bridge dimer complex was synthesized by following Reaction Formula 2-2.

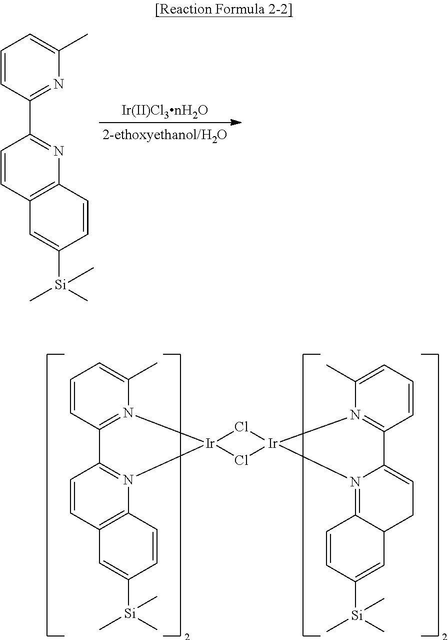

Iridium chloride (5 mmol) and 2-(6′-methylpyridyl)-6-trimethlysillylquinoline (10 mmol) was put in a solution (30 mL) of 2-ehoxyethanol and distilled H₂O (3:1) and refluxed for about 24 hours. After filtering the solids formed by adding water to the resulting solution, the solids were washed in several times with distilled water to obtain chloro-bridged dimer complex.

3) Iridium(III) (2-(6′-methylpyridyl)-6-trimethylsilylquinoline-N,C2′)(2,4-pentanedionate-O,O)[A-11]

A-11 compound was synthesized by following Reaction Formula 2-3.

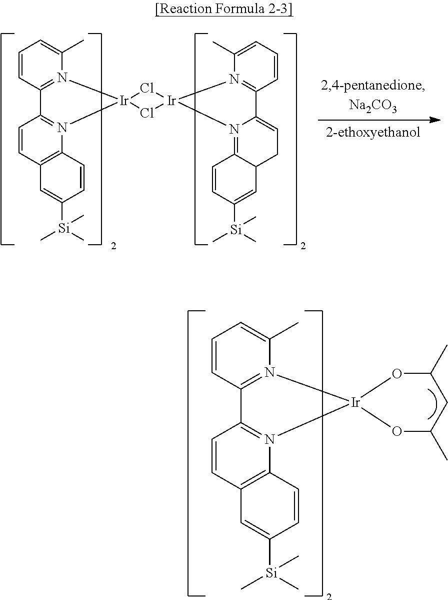

The above chloro-bridged dimer complex (1 mmol), 2,4-pentanedione (3 mmol) and Na₂CO₃(6 mmol) were put into 2-ethoxyethanol (30 mL) and refluxed for about 24 hours. The resulting solution was cooled, and distilled water was added. The resulting solution was filtered to obtain solids. The solids were dissolved in dichloromethane and filtered using silica gel. The solids were re-crystallized with dichloromethane and methanol to obtain A-11 compound.

### 3. Synthesis of A-56 Compound

Iridium(III) (2-(6′-methylpyridyl)-6-methylquinoline-N,C2′)(2,2,6,6-tetramethyl-3,5-heptanedionate-O,O) (A-56 compound) was synthesized by following Reaction Formula 3.

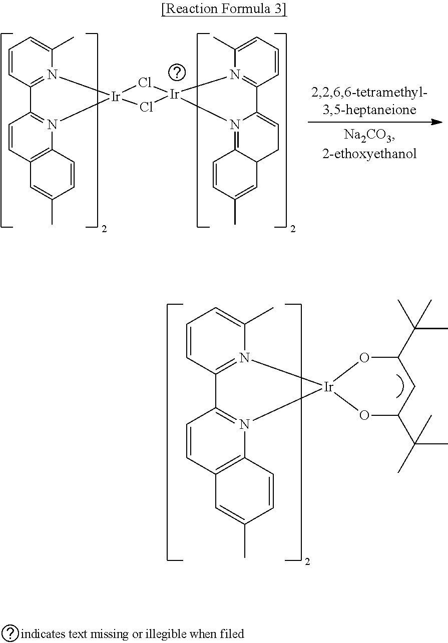

The above chloro-bridged dimer complex (1 mmol) in the Reaction Formula 1-2, 2,2,6,6-tetramethyl-3,5-heptaneione (3 mmol) and Na₂CO₃ (6 mmol) were put into 2-ethoxyethanol (30 mL) and refluxed for about 24 hours. The resulting solution was cooled, and distilled water was added. The resulting solution was filtered to obtain solids. The solids were dissolved in dichloromethane and filtered using silica gel. The solids were re-crystallized with dichloromethane and methanol to obtain A-56 compound.

### 3. Synthesis of A-74 Compound

Iridium(III) (2-(6′-methylpyridyl)-6-trimethylsilylquinoline-N,C2′)(2,2,6,6-tetramethyl-3,5-heptanedionate-O,O) (A-74 compound) was synthesized by following Reaction Formula 4.

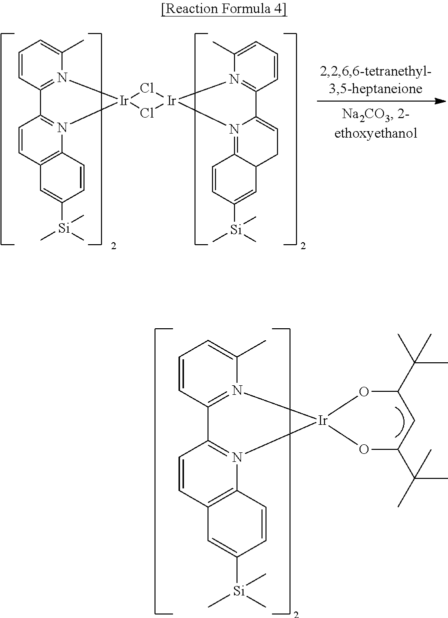

The above chloro-bridged dimer complex (1 mmol) in the Reaction Formula 2-2, 2,2,6,6-tetramethyl-3,5-heptaneione (3 mmol) and Na₂CO₃ (6 mmol) were put into 2-ethoxyethanol (30 mL) and refluxed for about 24 hours. The resulting solution was cooled, and distilled water was added. The resulting solution was filtered to obtain solids. The solids were dissolved in dichloromethane and filtered using silica gel. The solids were re-crystallized with dichloromethane and methanol to obtain A-74 compound.

### Example 1

### Emitting Diode with A-02 Compound as a Dopant

An ITO layer is deposited on a substrate and washed to form an anode. The substrate is loaded in a vacuum chamber, and a hole injecting layer (200 Å) of CuPC, a hole transporting layer (400 Å) of NPB, an emitting material layer (200 Å) of BAlq and A-02 compound (5%), an electron transporting layer (300 Å) of Alq3, an electron injecting layer (5 Å) of LiF, and a cathode (1000 Å) of aluminum are sequentially formed on the anode.

The emitting diode produces a brightness of 1880 cd/m² at an electric current of 0.9 mA and a voltage of 5.5 V and has the CIE(x) and CIE(y) of 0.660 and 0.322, respectively. The lifetime (a half of an initial brightness) is 6000 hours at 2000 cd/m².

### Example 2

### Emitting Diode with A-11 Compound as a Dopant

An ITO layer is deposited on a substrate and washed to form an anode. The substrate is loaded in a vacuum chamber, and a hole injecting layer (200 Å) of CuPC, a hole transporting layer (400 Å) of NPB, an emitting material layer (200 Å) of BAlq and A-11 compound (5%), an electron transporting layer (300 Å) of Alq3, an electron injecting layer (5 Å) of LiF, and a cathode (1000 Å) of aluminum are sequentially formed on the anode.

The emitting diode produces a brightness of 2001 cd/m² at an electric current of 0.9 mA and a voltage of 5.5 V and has the CIE(x) and CIE(y) of 0.662 and 0.323, respectively. The lifetime (a half of an initial brightness) is 6500 hours at 2000 cd/m².

### Example 3

### Emitting Diode with A-56 Compound as a Dopant

An ITO layer is deposited on a substrate and washed to form an anode. The substrate is loaded in a vacuum chamber, and a hole injecting layer (200 Å) of CuPC, a hole transporting layer (400 Å) of NPB, an emitting material layer (200 Å) of BAlq and A-56 compound (5%), an electron transporting layer (300 Å) of Alq3, an electron injecting layer (5 Å) of LiF, and a cathode (1000 Å) of aluminum are sequentially formed on the anode.

The emitting diode produces a brightness of 1892 cd/m² at an electric current of 0.9 mA and a voltage of 5.4 V and has the CIE(x) and CIE(y) of 0.663 and 0.332, respectively. The lifetime (a half of an initial brightness) is 5500 hours at 2000 cd/m².

### Example 4

### Emitting Diode with A-74 Compound as a Dopant

An ITO layer is deposited on a substrate and washed to form an anode. The substrate is loaded in a vacuum chamber, and a hole injecting layer (200 Å) of CuPC, a hole transporting layer (400 Å) of NPB, an emitting material layer (200 Å) of BAlq and A-74 compound (5%), an electron transporting layer (300 Å) of Alq3, an electron injecting layer (5 Å) of LiF, and a cathode (1000 Å) of aluminum are sequentially formed on the anode.

The emitting diode produces a brightness of 2024 cd/m² at an electric current of 0.9 mA and a voltage of 5.3 V and has the CIE(x) and CIE(y) of 0.665 and 0.331, respectively. The lifetime (a half of an initial brightness) is 6000 hours at 2000 cd/m².

### Comparative Example 1

### Emitting Diode with (Ir(2-phq)₂(acac) as a Dopant

An ITO layer is deposited on a substrate and washed to form an anode. The substrate is loaded in a vacuum chamber, and a hole injecting layer (200 Å) of CuPC, a hole transporting layer (400 Å) of NPB, an emitting material layer (200 Å) of BAlq and (Ir(2-phq)₂(acac) (7%), an electron transporting layer (300 Å) of Alq3, an electron injecting layer (5 Å) of LiF, and a cathode (1000 Å) of aluminum are sequentially formed on the anode.

The emitting diode produces a brightness of 1173 cd/m² at an electric current of 0.9 mA and a voltage of 6.0 V and has the CIE(x) and CIE(y) of 0.606 and 0.375, respectively. The lifetime (a half of an initial brightness) is 4000 hours at 2000 cd/m².

### Comparative Example 1

### Emitting Diode with (Ir(btp)₂(acac) as a Dopant

An ITO layer is deposited on a substrate and washed to form an anode. The substrate is loaded in a vacuum chamber, and a hole injecting layer (200 Å) of CuPC, a hole transporting layer (400 Å) of NPB, an emitting material layer (200 Å) of BAlq and (Ir(btp)₂(acac) (7%), an electron transporting layer (300 Å) of Alq3, an electron injecting layer (5 Å) of LiF, and a cathode (1000 Å) of aluminum are sequentially formed on the anode.

The emitting diode produces a brightness of 780 cd/m² at an electric current of 0.9 mA and a voltage of 7.5 V and has the CIE(x) and CIE(y) of 0.659 and 0.329, respectively. The lifetime (a half of an initial brightness) is 2500 hours at 2000 cd/m².

The properties and characteristics of the emitting diode in Example 1 to Example 4, Comparative Example 1 and Comparative Example 2 are listed in Table 1. (voltage [V], electric current [mA], brightness [cd/m²], current efficiency [cd/A], power efficiency [lm/W], lifetime [hr])

TABLE 1

| | | | | Current | Power | | | |
|---|---|---|---|---|---|---|---|---|
| | volt- | electric | Bright- | effi- | effi- | CIE | CIE | life- |
| | age | current | ness | ciency | ciency | (X) | (Y) | time |
| Ex. 1 | 5.5 | 0.9 | 1880 | 18.8 | 10.7 | 0.660 | 0.322 | 6000 |
| Ex. 2 | 5.5 | 0.9 | 2001 | 20.0 | 11.4 | 0.662 | 0.323 | 6500 |
| Ex. 3 | 5.4 | 0.9 | 1892 | 18.9 | 11.0 | 0.663 | 0.332 | 5500 |
| Ex. 4 | 5.3 | 0.9 | 2024 | 20.2 | 12.0 | 0.665 | 0.331 | 6000 |
| Com. | 6.0 | 0.9 | 1173 | 11.7 | 6.2 | 0.606 | 0.375 | 4000 |
| Ex. 1 | | | | | | | | |
| Com. | 7.5 | 0.9 | 780 | 7.8 | 3.3 | 0.659 | 0.329 | 2500 |
| Ex. 2 | | | | | | | | |

As shown in Table 1, the emitting diode using the red phosphorescent compound has advantages in efficiency, lifetime and color purity than the related art compound.

It will be apparent to those skilled in the art that various modifications and variations can be made in the present invention without departing from the spirit or scope of the invention. Thus, it is intended that the present invention cover the modifications and variations of this invention provided they come within the scope of the appended claims and their equivalents.

What is claimed is:

1. A red phosphorescent compound having the following formula: 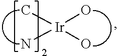
wherein 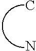
is 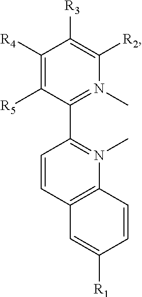
and R1 is selected from a group including C1˜C6 alkyl, C1˜C6 alkoxy, trimethylsilyl, trifluoromethyl, halogen and cyanide, and wherein each of R2, R3, R4 and R5 is independently selected from a group including hydrogen, C1˜C6 alkyl, C1˜C6 alkoxy, halogen, trimethylsilyl and trifluoromethyl.

2. The compound according to claim 1, wherein the C1˜C6 alkyl includes methyl, ethyl, n-propyl, i-propyl, n-butyl, and t-butyl, and the C1˜C6 alkoxy includes methoxy, ethoxy, n-propoxy, i-propoxy, n-butoxy, i-butoxy and t-butoxy, and wherein the halogen includes fluorine (F), chorine (Cl), bromine (Br) and iodine (I).

3. The compound according to claim 1, wherein 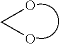
is selected from 2,4-ppentanedione, 2,2,6,6-tetramethylheptane-3,5-dione, 1,3-propanedione, 1,3-butanedione, 3,5-heptanedione, 1,1,1-trifluoro-2,4-pentanedione, 1,1,1,5,5,5-hexafluoro-2,4-pentanedione and 2,2-dimethyl-3,5-hexanedione.

4. The compound according to claim 1, wherein 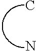
is selected from followings:

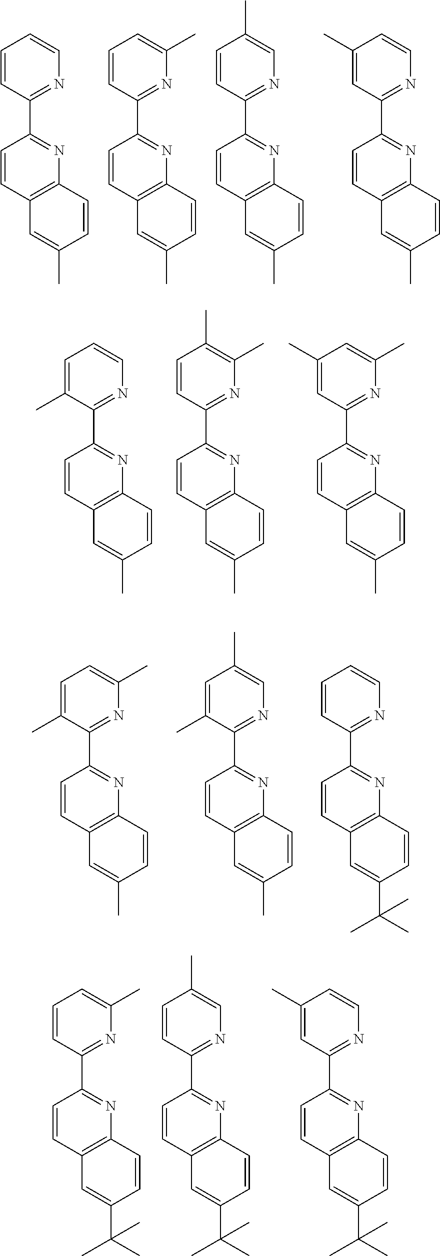

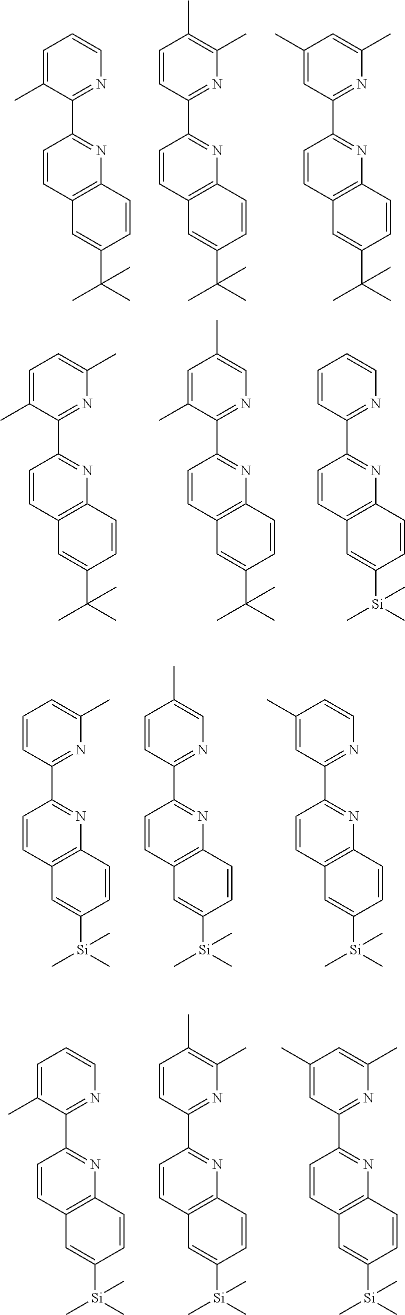

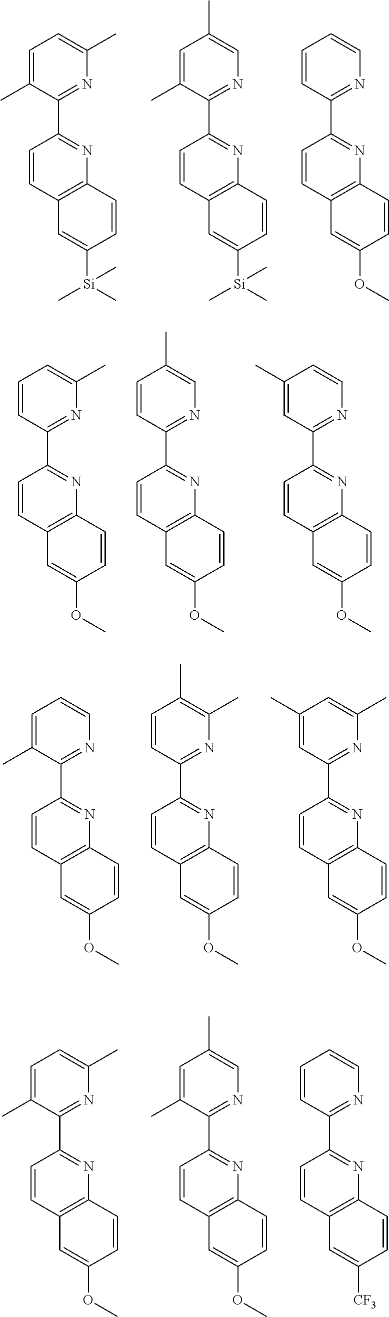

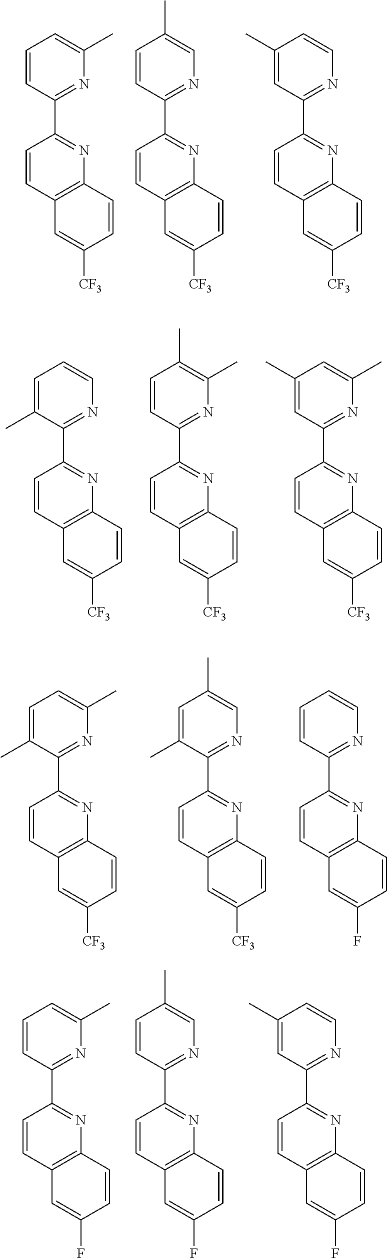

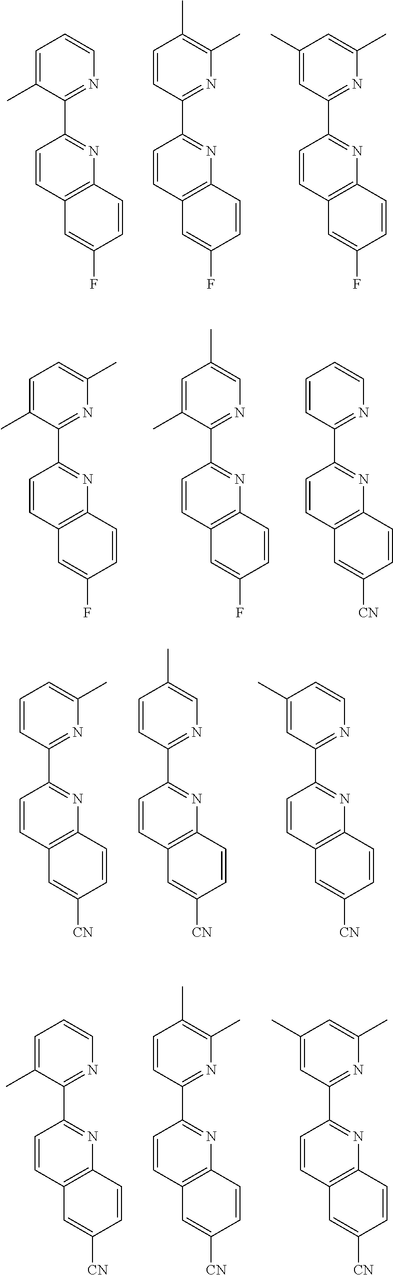

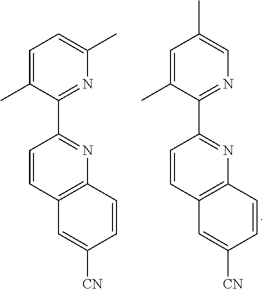

5. The compound according to claim 1, wherein the compound includes one of followings:

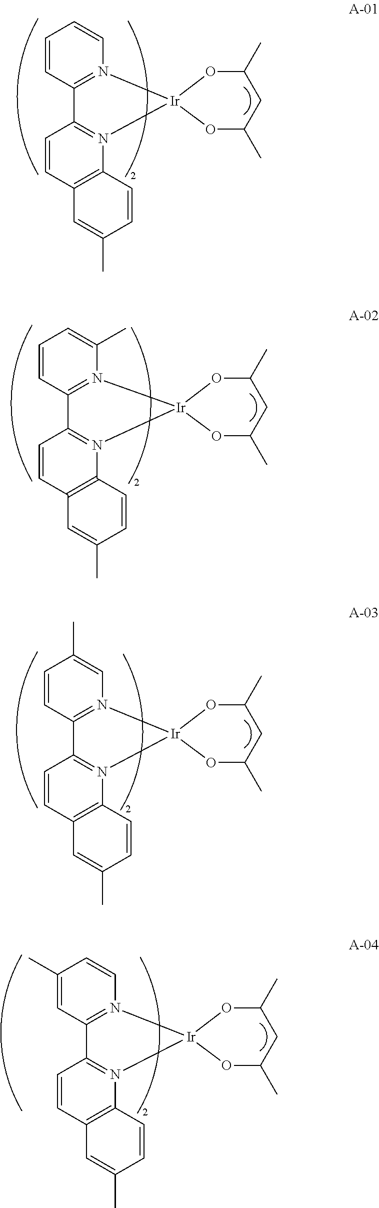

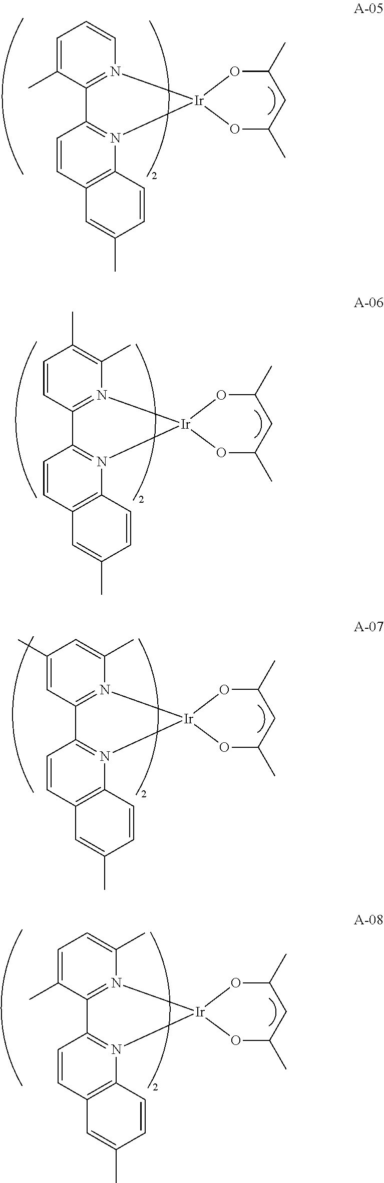

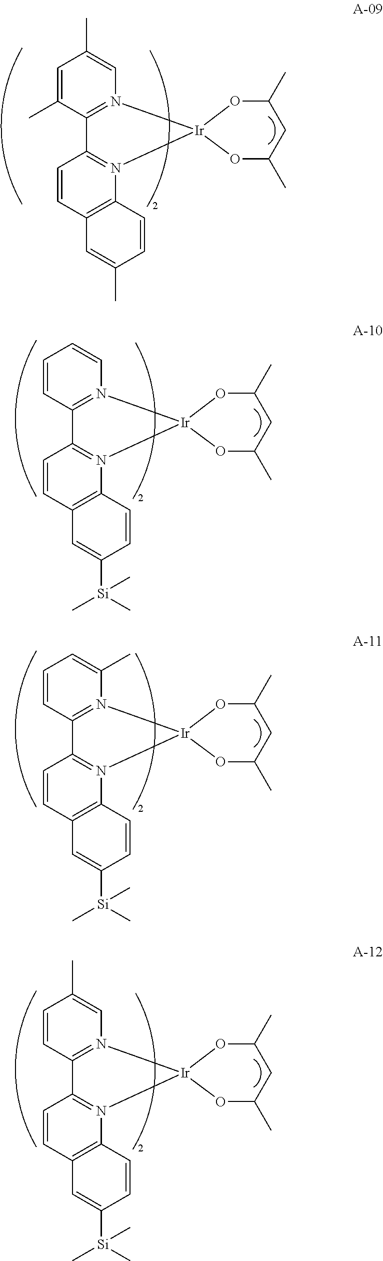

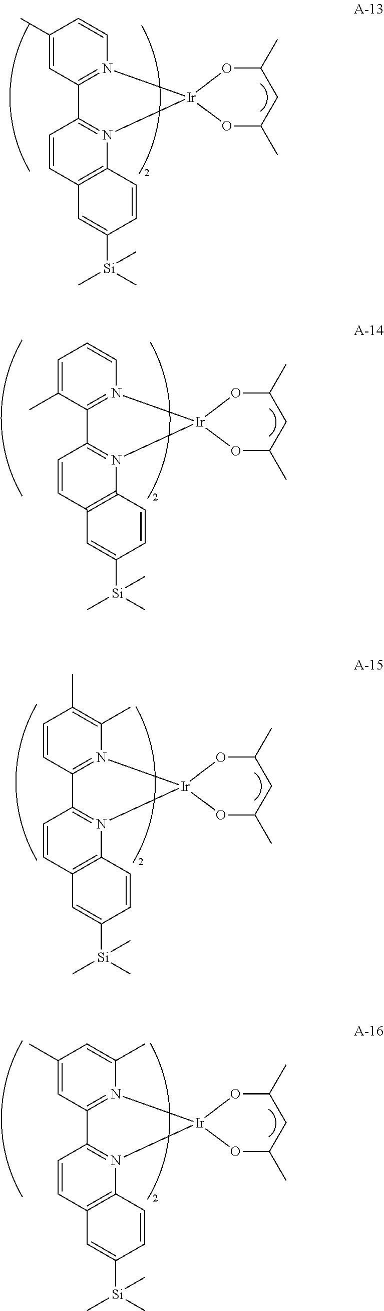

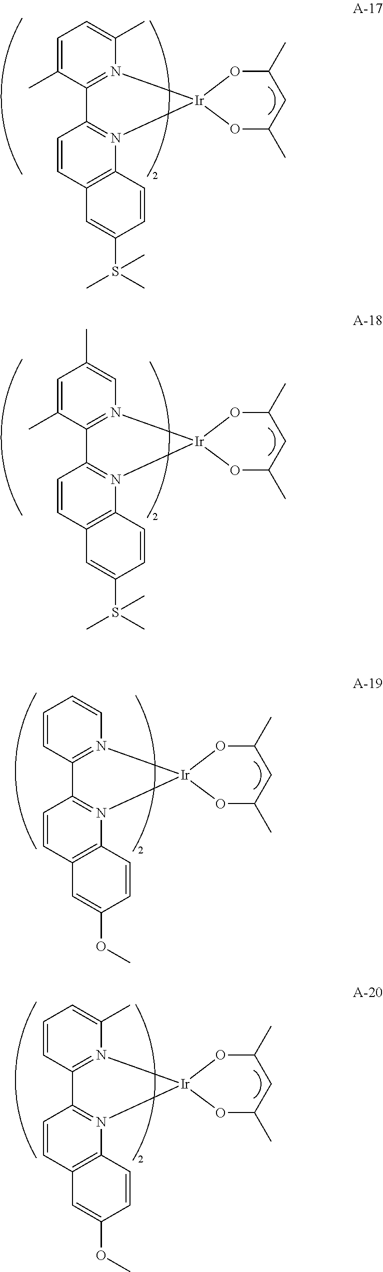

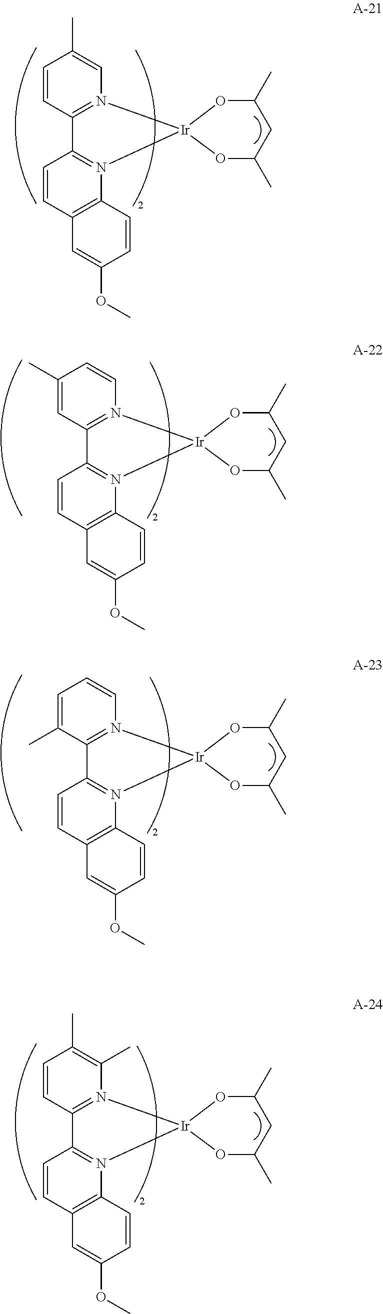

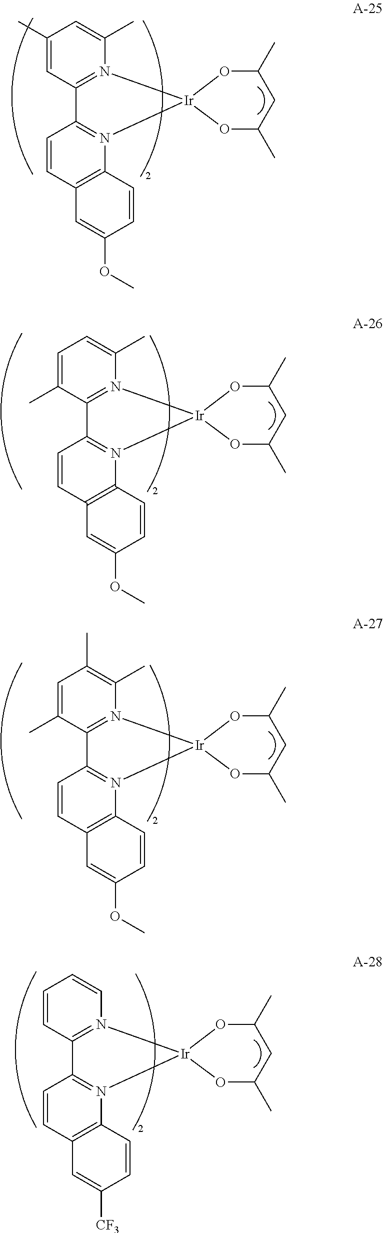

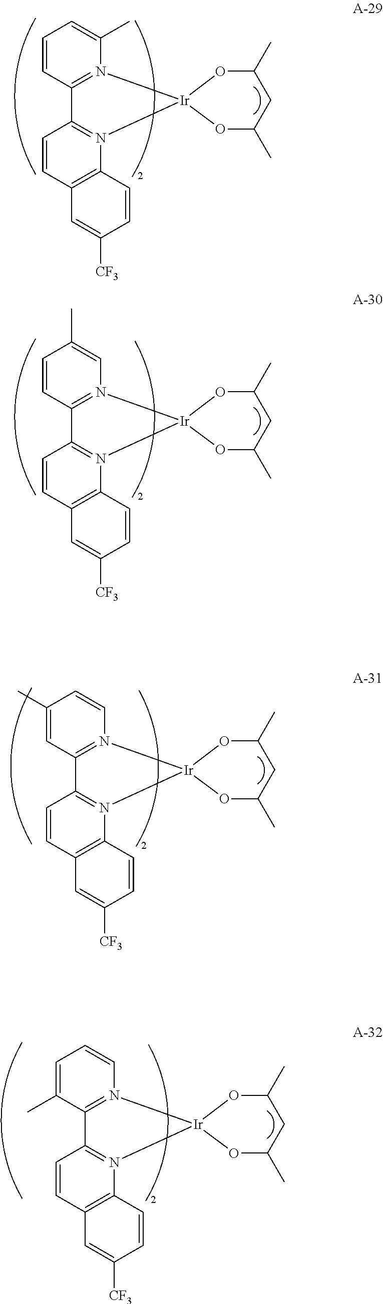

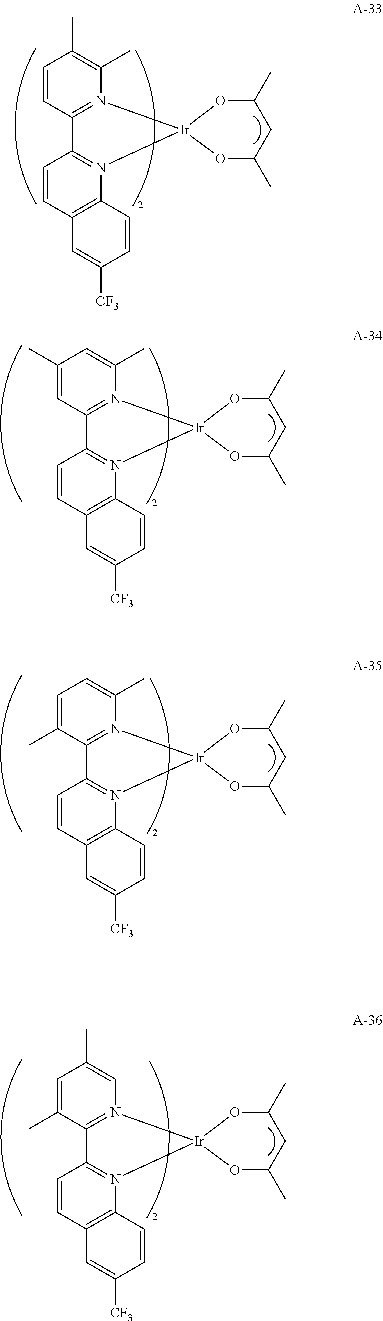

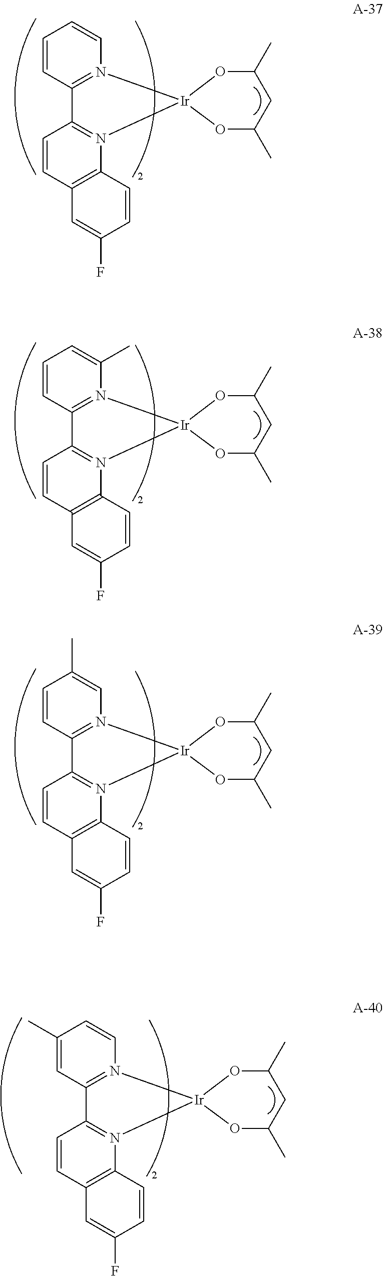

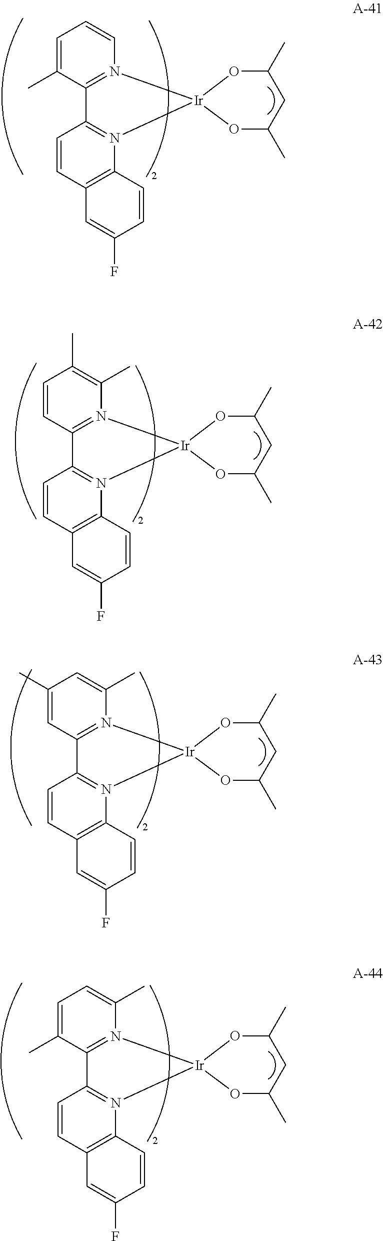

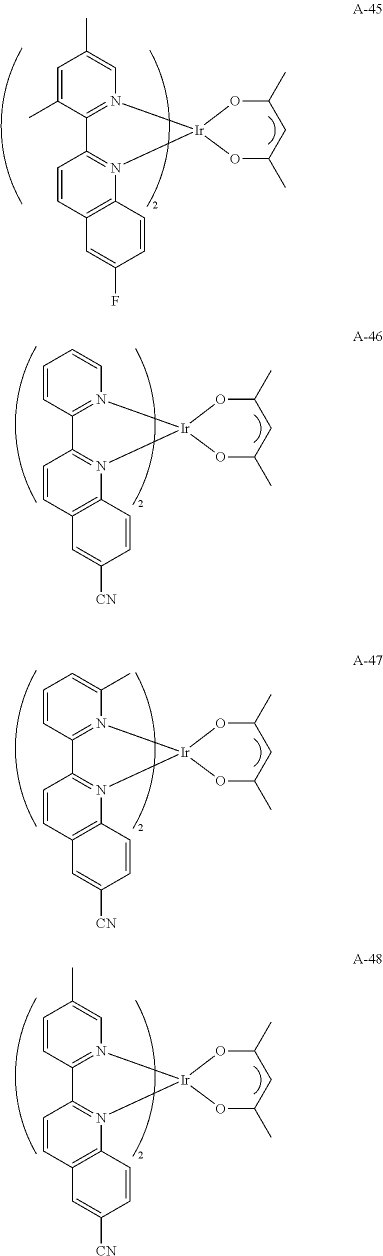

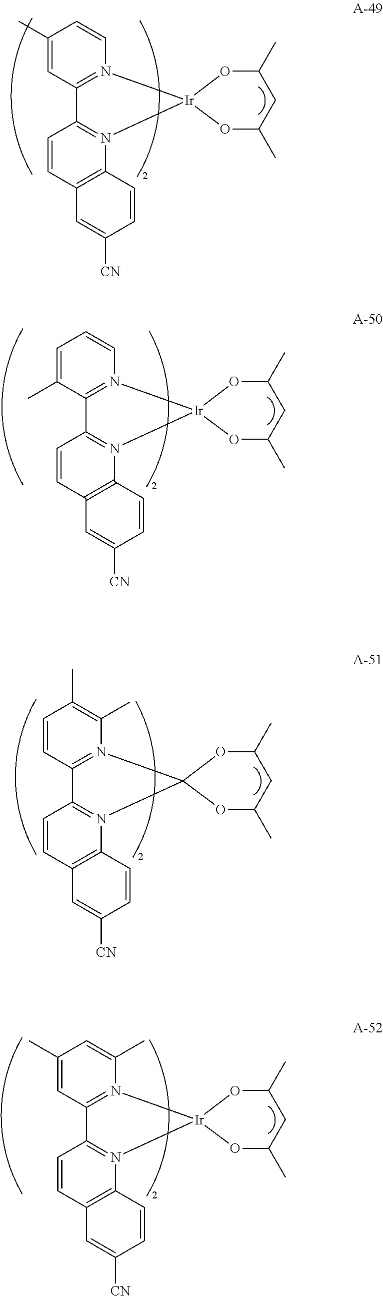

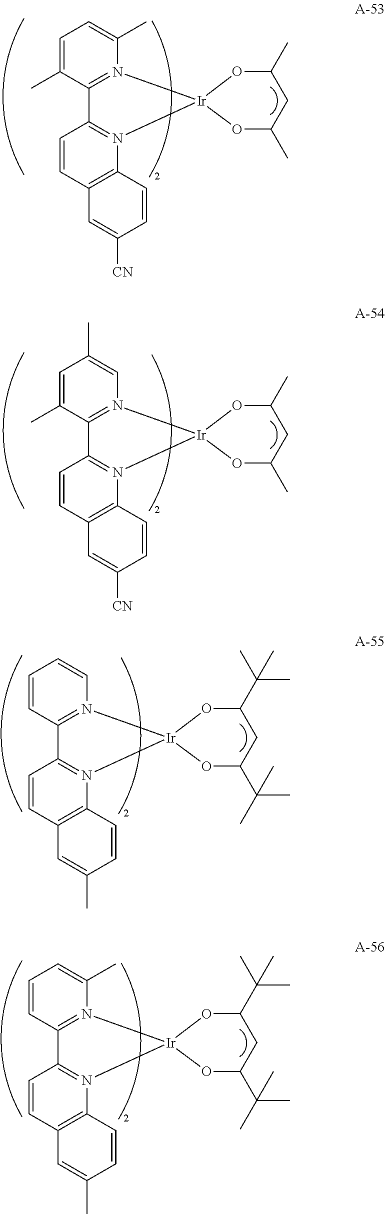

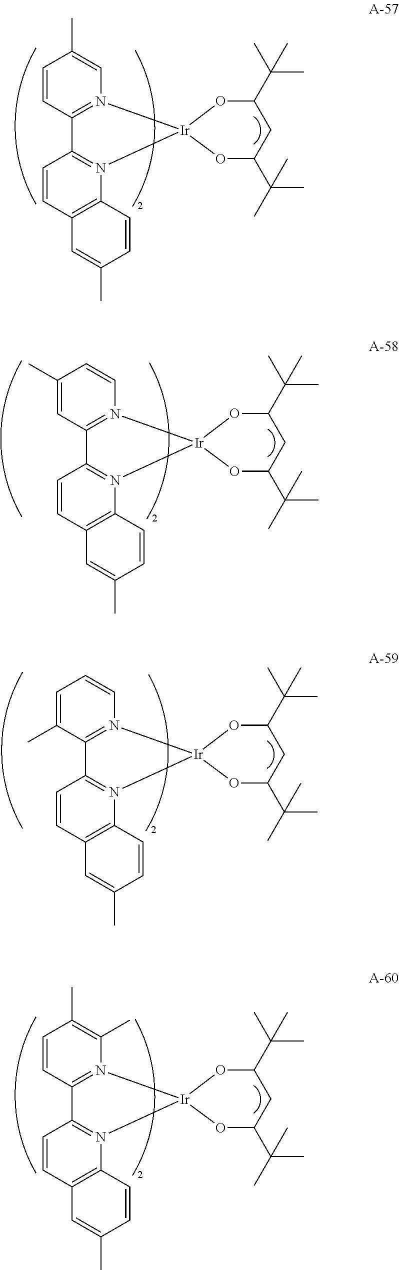

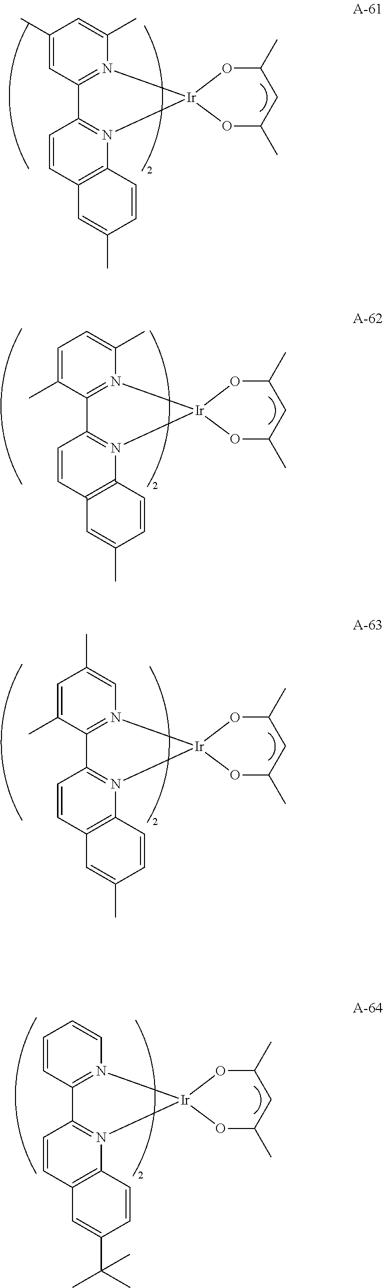

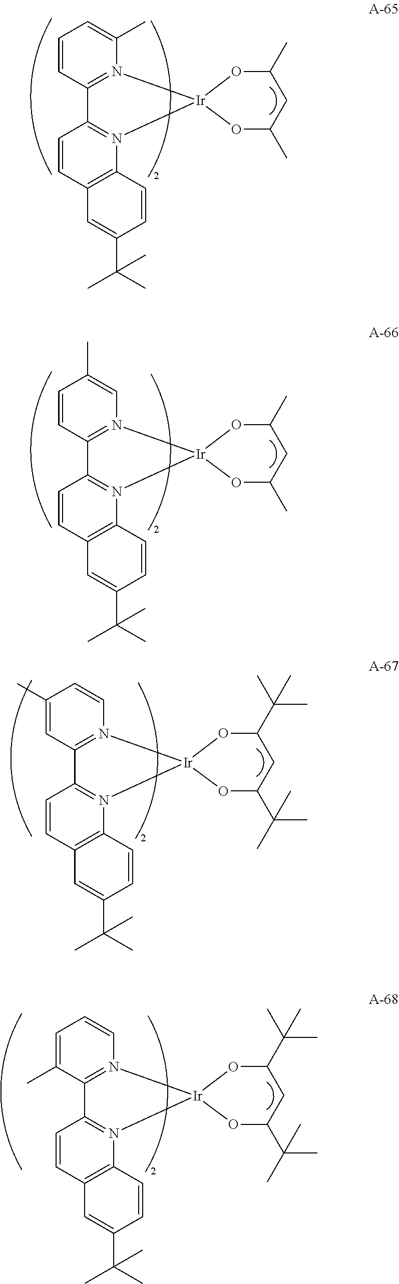

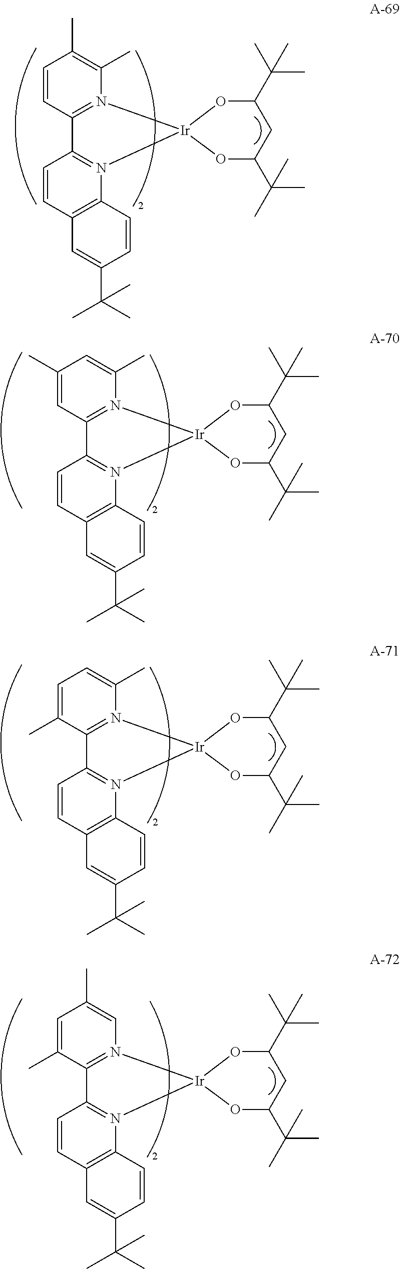

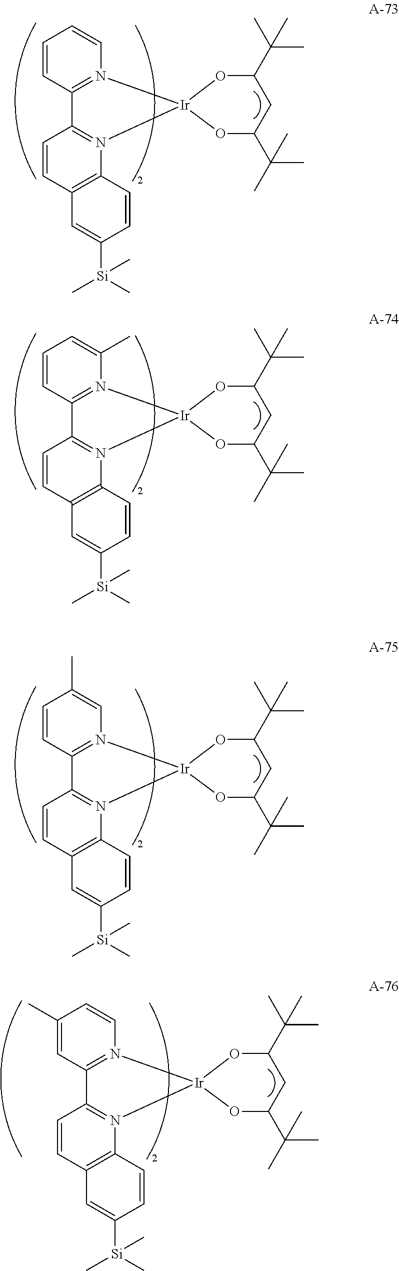

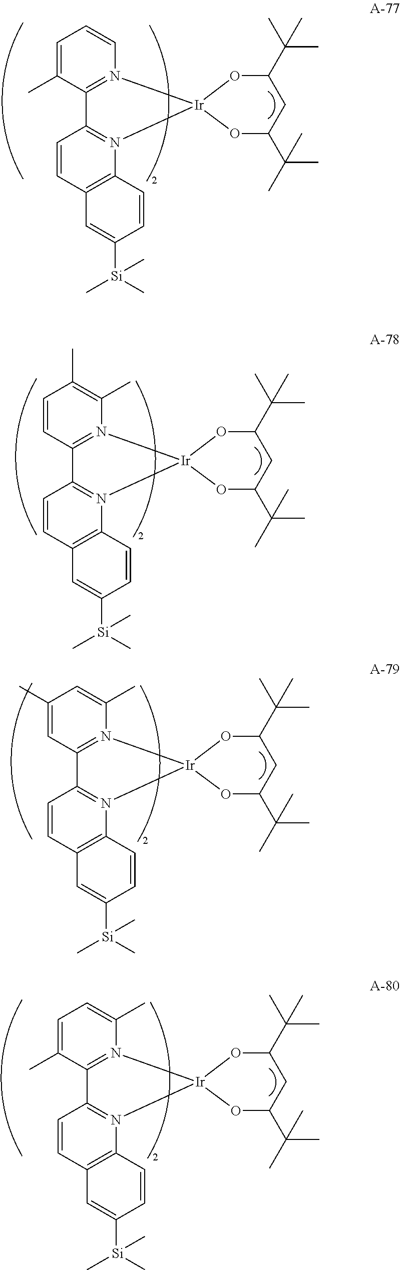

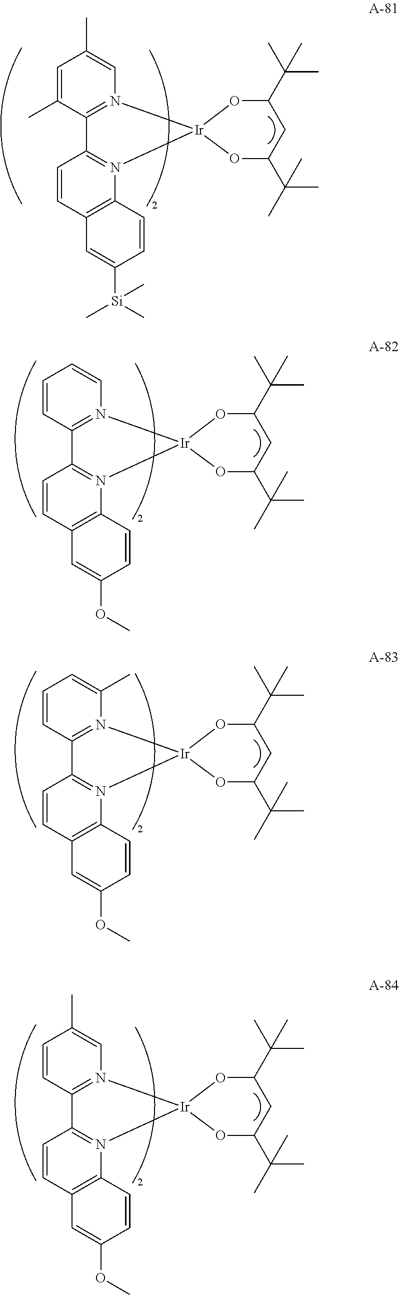

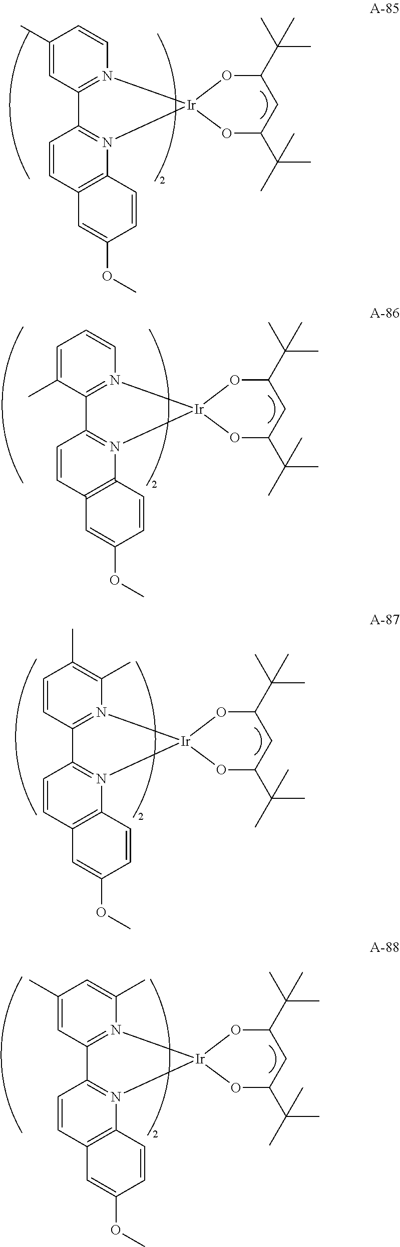

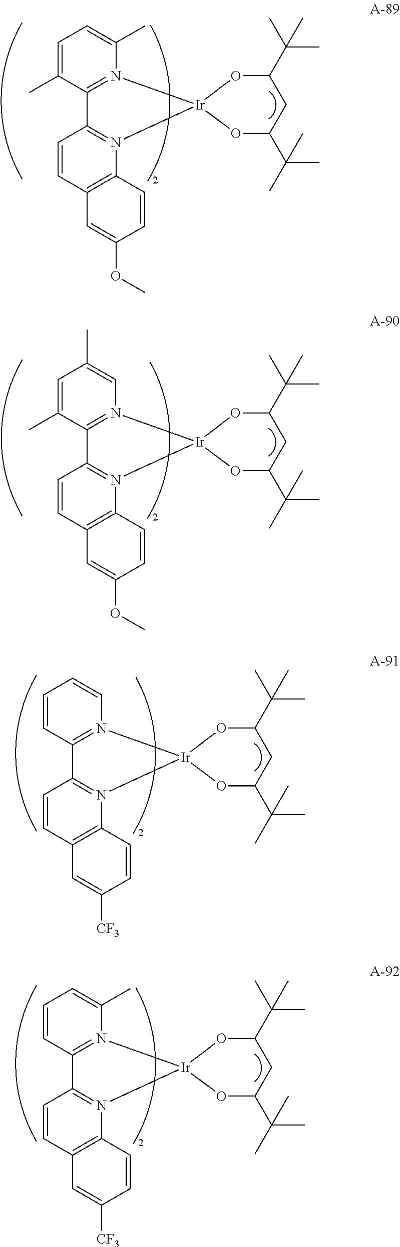

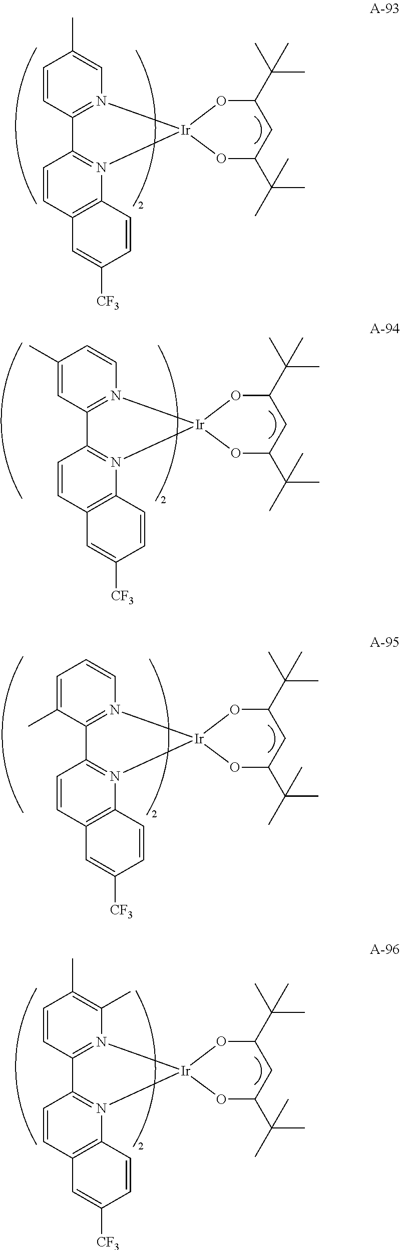

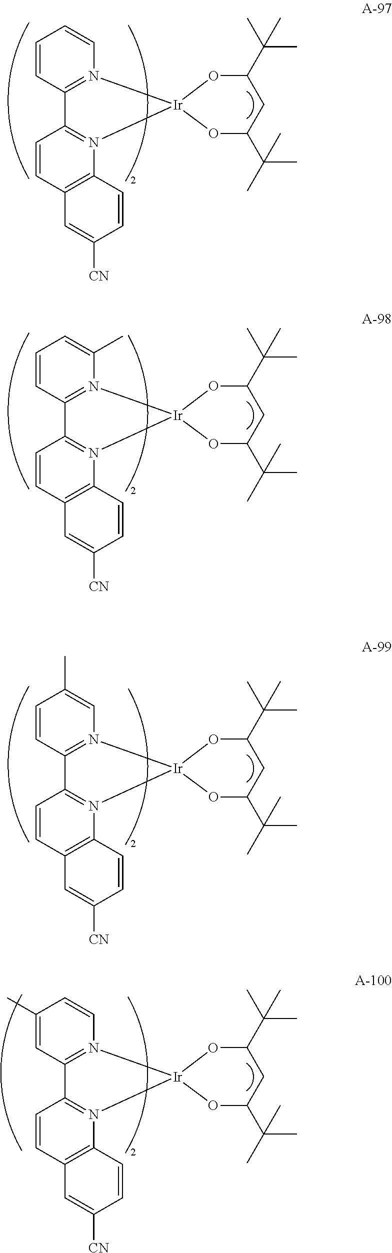

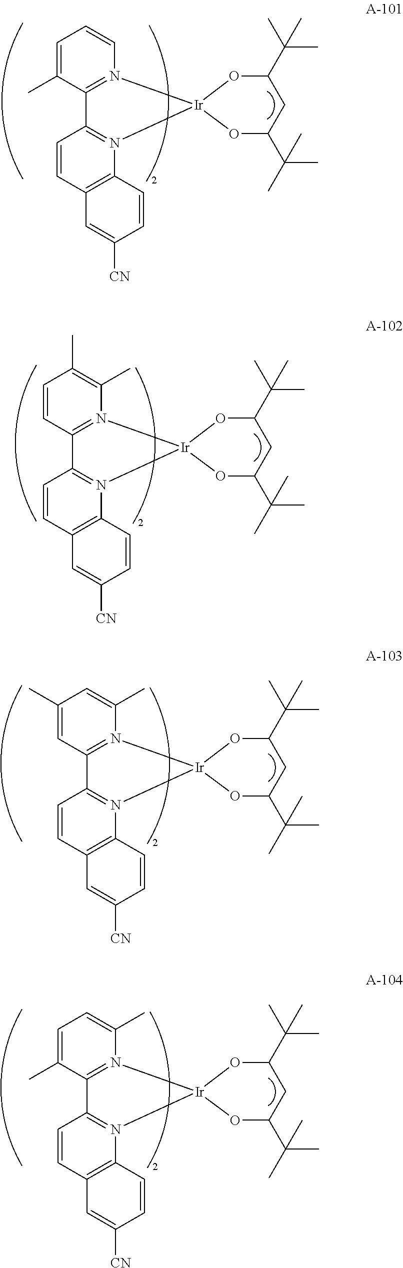

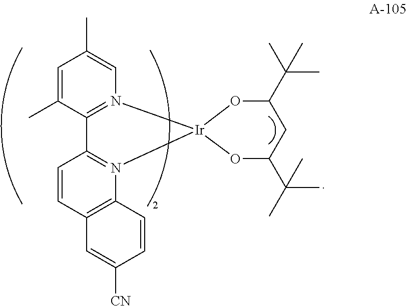

6. An organic light emitting diode device, comprising:
a first electrode;
a second electrode facing the first electrode; and
an emitting material layer between the first and second electrodes and including a red phosphorescent compound having the following formula: 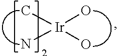
wherein 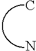
is 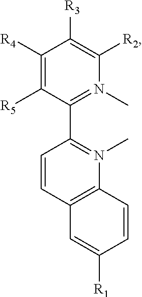
and R1 is selected from a group including C1˜C6 alkyl, C1˜C6 alkoxy, trimethylsilyl, trifluoromethyl, halogen and cyanide, and wherein each of R2, R3, R4 and R5 is independently selected from a group including hydrogen, C1˜C6 alkyl, C1˜C6 alkoxy, halogen, trimethylsilyl and trifluoromethyl.

7. The device according to claim 6, wherein the red phosphorescent compound is used as a dopant of the emitting material layer.

8. The device according to claim 6, wherein the emitting material layer further includes a host formed of one of aluminum-metal complex, zinc-metal complex and carbazole derivative.

9. The device according to claim 8, wherein each of the aluminum-metal complex and the zinc-metal complex includes a ligand of at least one of phenylyl, biphenylyl, quinolyl, iso-quinolyl, methyl-quinolyl, dimethylquinolyl and dimethyl-iso-quinolyl, and the carbazole derivative is one of 4,4′-N,N′-dicarbazole-1,1-biphenyl and (N,N-dicarbazoyl-3,5-benzene.

10 The device according to claim 7, wherein the dopant is doped with a weight % of about 0.1 to 50.
